(19) United States
(12) Patent Application Publication
(10) Pub. No.: US 2022/0238813 A1
(43) Pub. Date: Jul. 28, 2022

(54) ORGANIC LIGHT-EMITTING ELEMENT, DISPLAY APPARATUS, IMAGING APPARATUS, ELECTRONIC EQUIPMENT, LIGHTING APPARATUS, AND MOVING BODY

(71) Applicant: CANON KABUSHIKI KAISHA, Tokyo (JP)

(72) Inventors: Satoru Shiobara, Kanagawa (JP); Naoki Yamada, Tokyo (JP); Hirokazu Miyashita, Kanagawa (JP); Yosuke Nishide, Kanagawa (JP); Jun Kamatani, Tokyo (JP); Hiroki Ohrui, Tokyo (JP)

(21) Appl. No.: 17/575,435

(22) Filed: Jan. 13, 2022

(30) Foreign Application Priority Data
Jan. 22, 2021 (JP) 2021-008438

(51) Int. Cl. H01L 51/00; H01L 51/50

(52) U.S. Cl. CPC H01L 51/0071; H01L 51/0073; H01L 51/0072; H01L 51/5036; H01L 51/5012; H01L 2251/552; H01L 51/5004

(57) ABSTRACT

An organic light-emitting element including a first electrode, a second electrode, and a light-emitting layer located between the first electrode and the second electrode. The light-emitting layer contains a first organic compound material, a second organic compound that is a delayed fluorescent material, and a third organic compound that is a light-emitting material. In the second organic compound, an electron is transferred from a plurality of occupied molecular orbitals (OMO) to a lowest unoccupied molecular orbital (LUMO) in a second excited triplet state.

### BACKGROUND OF THE INVENTION

### Field of the Invention

The present disclosure relates to an organic light-emitting element and an image display apparatus.

### Description of the Related Art

An organic light-emitting element (also referred to as an organic electroluminescent element or an organic EL element) is an electronic element that includes a pair of electrodes and an organic compound layer between the electrodes. Electrons and holes are injected from the pair of electrodes to generate an exciton of a light-emitting organic compound in the organic compound layer. When the exciton returns to its ground state, the organic light-emitting element emits light.

With recent significant advances in organic light-emitting elements, various disclosures have been made to realize low drive voltage, various emission wavelengths, high-speed responsivity, and thin and light light-emitting elements.

To increase the luminescence efficiency of an organic light-emitting element, it is known to use a phosphorescent material or a delayed fluorescent material.

A phosphorescent material supplies energy to a triplet to use a triplet exciton for light emission. To supply energy to the triplet, it is necessary to supply energy to a singlet, which has higher excitation energy than the triplet exciton. On the other hand, it is known that a delayed fluorescent material directly converts a singlet exciton into light emission. Thus, for light emission at the same wavelength, a delayed fluorescent material can emit light only by supplying energy lower than energy supplied by a phosphorescent material.

Japanese Patent Laid-Open No. 2015-179809 (hereinafter referred to as PTL 1) discloses an efficient organic light-emitting element that includes a first organic compound, a second organic compound, and a third organic compound in decreasing order of lowest excited singlet energy, the second organic compound being a delayed fluorescent material. It is known that the second organic compound, which is a delayed fluorescent material, plays a role in converting a lowest excited triplet exciton in an organic layer into a higher singlet exciton.

Japanese Patent Laid-Open No. 2011-216640 (hereinafter referred to as PTL2) discloses that an exposed surface area of a bond is used as a numerical value indicating the durability of an organic compound and as a measure of the durability of the organic compound.

An organic light-emitting element described in PTL1 includes a second organic compound, which is a delayed fluorescent material. A higher singlet exciton is generated in a light-emitting element including a delayed fluorescent material. Thus, the first organic compound and the second organic compound should be stable organic compounds. However, PTL1 does not consider the stability of the organic light-emitting element including the second organic compound and leaves room for improvement in the durability of the organic light-emitting element.

### SUMMARY OF THE INVENTION

In view of such situations, the present disclosure provides an organic light-emitting element with high durability by using a stable organic compound.

The present disclosure provides an organic light-emitting element including a first electrode, a second electrode, and a light-emitting layer located between the first electrode and the second electrode, wherein the light-emitting layer contains a first organic compound, a second organic compound that has lower lowest excited singlet energy than the first organic compound and is a delayed fluorescent material, and a third organic compound that is a light-emitting material with lower lowest excited singlet energy than the second organic compound, and at least one of an exposed surface area of a single bond in a structure of the first organic compound and an exposed surface area of a single bond in a structure of the second organic compound is 91 or more.

Further features of the present disclosure will become apparent from the following description of exemplary embodiments with reference to the attached drawings.

### BRIEF DESCRIPTION OF THE DRAWINGS

FIGS. 1A to 1C are conceptual diagrams of an exposed surface area according to an embodiment.

FIGS. 2A and 2B are conceptual diagrams of grid approximation in a method for calculating an exposed surface area according to an embodiment.

FIG. 3A is a diagram of molecular orbitals of Exemplary Compound 1. FIG. 3B is a diagram of molecular orbitals of Exemplary Compound 5. FIG. 3C is a diagram of molecular orbitals of Exemplary Compound 2.

FIG. 4A is a schematic cross-sectional view of an example of a pixel of a display apparatus according to an embodiment of the present disclosure. FIG. 4B is a schematic cross-sectional view of an example of a display apparatus including an organic light-emitting element according to an embodiment of the present disclosure.

FIG. 5 is a schematic view of an example of a display apparatus according to an embodiment of the present disclosure.

FIG. 6A is a schematic view of an example of an imaging apparatus according to an embodiment of the present disclosure. FIG. 6B is a schematic view of an example of electronic equipment according to an embodiment of the present disclosure.

FIG. 7A is a schematic view of an example of a display apparatus according to an embodiment of the present disclosure. FIG. 7B is a schematic view of an example of a foldable display apparatus.

FIG. 8A is a schematic view of an example of a lighting apparatus according to an embodiment of the present disclosure. FIG. 8B is a schematic view of an example of an automobile with a vehicle lamp according to an embodiment of the present disclosure.

FIG. 9A is a schematic view of an example of a wearable device according to an embodiment of the present disclosure. FIG. 9B is a schematic view of an example of a wearable device according to an embodiment of the present disclosure, which has an imaging apparatus.

### DESCRIPTION OF THE EMBODIMENTS

An organic light-emitting element according to an embodiment of the present disclosure is an organic light-emitting element including a first electrode, a second electrode, and a light-emitting layer located between the first electrode and the second electrode, wherein the light-emitting layer contains a first organic compound, a second organic compound that has lower lowest excited singlet energy than the first organic compound and is a delayed fluorescent material, and a third organic compound that is a light-emitting material with lower lowest excited singlet energy than the second organic compound, and at least one of an exposed surface area of a single bond in a structure of the first organic compound and an exposed surface area of a single bond in a structure of the second organic compound is 91 or more. Both of the exposed surface areas of the single bond can be 91 or more. At least one of the exposed surface areas of the single bond can be 100 or more, and both of the exposed surface areas of the single bond can be 100 or more.

In the present specification, a delayed fluorescent material is an organic compound with a small difference between the lowest excited singlet energy and the lowest excited triplet energy. Excited energy of a lowest excited triplet can be transferred to a lowest excited singlet at room temperature. In the present embodiment, high energy may be applied to the first organic compound and the second organic compound during the energy transfer, and the first organic compound and the second organic compound should withstand the high energy. An organic compound with a large exposed surface area has high durability. Thus, an organic compound with a large exposed surface area can be used to improve the durability of the organic light-emitting element according to the present embodiment.

The exposed surface area is the surface area of an exposed portion of a molecule around a cleavage site (an aryl-aryl single bond). Thus, the exposed surface area decreases with increasing steric hindrance around the aryl-aryl single bond. Small steric hindrance (a large exposed surface area) causes a radical pair to recombine easily and return to the ground state, thus resulting in less degradation. Thus, the organic light-emitting element has a long drive lifetime. The second organic compound is a material that converts a triplet exciton into a singlet exciton. This means that the second organic compound is partly present in a lowest excited triplet state (T₁). Upon further optical absorption or energy transfer, the transient T₁ state in the light-emitting layer is excited to a higher excited triplet state. This causes degradation. Thus, a high exposed surface area results in a low probability of degradation caused by bond cleavage and results in an element with high drive durability.

In the present specification, the exposed surface area is uniquely determined by the following calculation method. First, the stable structure of the lowest excited triplet state T₁ among multiple conformations is determined. More specifically, computational chemistry software, such as Cache, was used to search for the most stable structure among optimized structures of conformers by a molecular force field calculation method (MM3). A stable structure of the lowest excited triplet state T₁ was determined by the density functional theory (DFT) using the most stable structure among the multiple conformations determined by the MM3 as an initial structure and using computational chemistry software, such as Turbomole. For the DFT, B3LYP may be used as a functional, and deft-SV(P) may be used as a basis function. Computational chemistry software with a similar function may be used for the MM3 calculation and the DFT calculation.

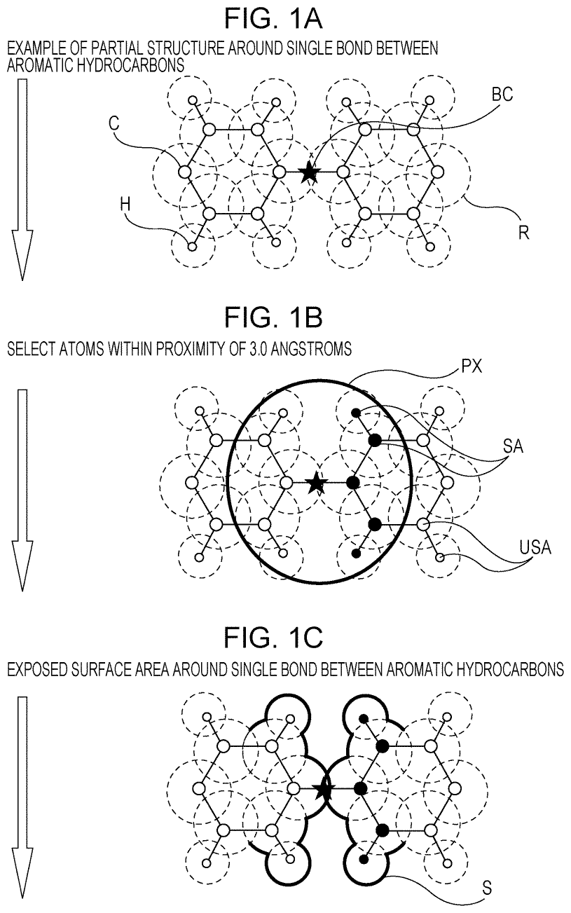

The exposed surface area of each single bond between aromatic hydrocarbons is then determined. For the exposed surface area of a single bond between aromatic hydrocarbons, atoms within a certain distance (proximity=3.0 angstroms) from the midpoint of the single bond between the aromatic hydrocarbons are selected, and the sum of the exposed surface areas belonging to the atoms is calculated. FIGS. 1A to 1C are conceptual diagrams of an exposed surface area. In FIGS. 1A to 1C, BC denotes the midpoint of a single bond between aromatic hydrocarbons. R denotes the surface of a sphere that has the van der Waals radius (Bondi value) plus the probe radius from the center of each atom. C denotes a carbon atom, and H denotes a hydrogen atom. PX indicates a region within 3.0 units from BC. SA indicates atoms within the PX, and USA indicates atoms outside the PX. S denotes the exposed surface area of a single bond of interest. Although FIGS. 1A to 1C are two-dimensionally illustrated for the sake of simplicity, actual calculation is performed in three dimensions.

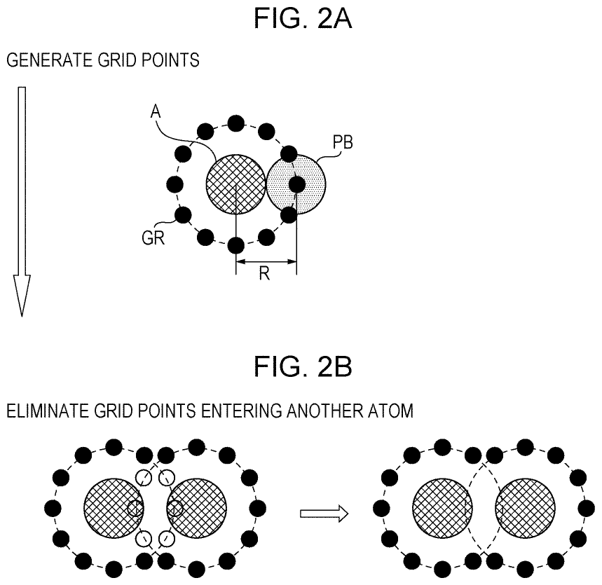

The exposed surface area may be the area of the surface formed by the passage of the center of a probe sphere with a probe radius of 1.7 angstroms. More specifically, approximate calculation is possible by generating grid points on the surface of the van der Waals radius of the molecule (Bondi value)+the probe radius and counting the number of grid points except grid points entering another atom. FIGS. 2A and 2B illustrate a method of calculating an exposed surface area using grid points. In FIGS. 2A and 2B, A denotes an atom in which the van der Waals radius is considered, PB denotes a probe sphere, and GR denotes a grid point. R denotes the van der Waals radius plus the probe radius. Although FIGS. 2A and 2B are two-dimensionally illustrated for the sake of simplicity, actual calculation is performed in three dimensions.

Grid points were generated by dividing each plane into 25 equilateral triangles based on a regular icosahedron inscribed in a sphere with the van der Waals radius+the probe radius of each atom and by using the vertices of a geodesic dome formed by projecting the vertices of each equilateral triangle onto the circumscribed sphere. This generates 252 grid points. Although the calculation of the exposed surface area in the present embodiment is not limited to this approximation, it is desirable to generate at least 252 grid points for approximation. After the exposed surface area of each single bond is calculated, the lowest value of the exposed surface areas is selected.

In the present embodiment, at least one of the first organic compound and the second organic compound has an exposed surface area of 91 or more. Satisfying this can achieve both high luminescence efficiency due to the use of a delayed fluorescent material and a long element lifetime.

Molecules in a film have various association states, and their energy states have the density of states. Although the level relation of T₁ energy can be T₁ (first organic compound) >T₁ (second organic compound), when the T₁ energy is transferred to the second organic compound, reverse intersystem crossing may be considered, and it is therefore not necessary to limit the absolute value of the T₁ energy itself. In such a case, the T₁ energy returns slightly from the second organic compound to the first organic compound, and therefore the first organic compound can have a large exposed surface area. In other words, when T₁ (first organic compound) >T₁ (second organic compound) is satisfied, the transient T₁ state of the second organic compound is present for a longer time, and therefore the second organic compound can have a larger exposed surface area than the first organic compound. The first organic compound may have a larger exposed surface area than the second organic compound.

Although confining a triplet exciton in the light-emitting layer is not a requirement, the T₁ level of the second organic compound in the light-emitting layer can be lower than the T₁ level of an organic compound used in an adjacent charge-blocking layer. This can reduce the transfer of excitons in the T₁ state to the adjacent layer and retain excitons in the T₁ state in the light-emitting layer. Thus, a second organic compound contributes to higher luminescence efficiency. An electric charge to be blocked may be a hole or an electron.

A light-emitting layer of an organic light-emitting element according to the present disclosure is composed of at least three different organic compounds. A first organic compound is also referred to as a host material, a second organic compound is also referred to as an assist material, and a third organic compound is also referred to as a light-emitting material. The first organic compound serves as a host material and mainly transports a carrier. The second organic compound is a delayed fluorescent material and plays a role in converting a triplet exciton into a singlet exciton as an assist material and transferring the converted energy to another organic compound. Although the second organic compound converts a triplet exciton into a singlet exciton, this conversion does not have to occur on the orbit of the second organic compound. Any pathway is possible, provided that the energy received by another organic compound is a singlet exciton.

The second organic compound can have a small energy difference between S₁ and T₁. For singlet excitons and triplet excitons generated at a ratio of 1:3, this can convert a thermally deactivated triplet exciton into a singlet exciton to emit light.

A delayed fluorescent material can be identified by measuring the emission lifetime. In addition to an emission lifetime component of an excited singlet state (S₁) generated by initial excitation in a solution at room temperature or in a film doped with a low concentration of a host at room temperature, an excited singlet state generating from the lowest excited triplet state (T₁) by reverse intersystem crossing emits delayed fluorescence. Thus, the emission lifetime profile of delayed fluorescence is not at least single exponential decay and has emission properties of a short-lifetime component and a long-lifetime component.

A requirement for the characteristics of delayed fluorescence can be to eliminate overlap between the HOMO and LUMO molecular orbitals and thereby decrease exchange integral. This can decrease the energy difference between S₁ and T₁. The energy difference (ΔE_{S1IT1}) that facilitates delayed fluorescence is preferably less than 0.4 eV. This facilitates thermal reverse intersystem crossing of energy relaxed to T₁to S₁. The energy difference is more preferably 0.3 eV or less.

Furthermore, controlling electronic transition at a second excited triplet state (T₂) level for reverse intersystem crossing can control the rate of the reverse intersystem crossing. A measure T of the rate of reverse intersystem crossing is represented by the formula (1):

$$T = \frac{〈 {Ψ}_{{S}_{1}} \vert {H}_{SOC} \vert {Ψ}_{{T}_{1}} 〉}{Δ {E}_{{S}_{1} {T}_{1}}} + \frac{〈 {Ψ}_{{S}_{1}} \vert {H}_{SOC} \vert {Ψ}_{{T}_{2}} 〉}{Δ {E}_{{S}_{1} {T}_{2}}} \qquad ( 1 )$$

ΔE_{S1Tn} denotes the energy difference between S₁ and Tₙ. For each term of the measure T in the formula (1), the numerator represents the strength of spin-orbit coupling, and the denominator represents the proximity of excitation energy. In a typical delayed fluorescent material, S₁and T₁have similar electron densities, and the numerator of the first term is small. S₁and T₂ tend to have different electron densities, and the numerator of the second term is large.

Thus, increasing (Ψ_{S1}|H_{SOC}|Ψ_{T2}) increases delayed fluorescence.

S₁and T₁often have a HOMO-to-LUMO transition orbital as a main component. On the other hand, transition from T₂ includes a LUMO shared transition type, which shares the LUMO, and a HOMO shared transition type, which shares the HOMO. The LUMO shared transition type includes a molecule in which T₂ has as a main component a transition orbital from an occupied molecular orbital (OMO) other than the HOMO to the LUMO. To increase (Ψ_{S1}|H_{SOC}|Ψ_{T2}), the spin-orbit coupling between the HOMO and the OMO is increased. In this case, increasing the overlap between the OMO and the HOMO increases the spin-orbit coupling.

On the other hand, the HOMO shared transition type includes a molecule in which T₂ has as a main component a transition orbital from the HOMO to an unoccupied molecular orbital (UMO) other than the LUMO. To increase (Ψ_{S1}|H_{SOC}|Ψ_{T2}), the spin-orbit coupling between the LUMO and the UMO is increased. In this case, increasing the overlap between the UMO and the LUMO increases the spin-orbit coupling.

In the present specification, molecular orbital calculation was performed by the following method. A widely used density functional theory (DFT) was used for the calculation. B3LYP was used as the functional, and 6-31G* was used as the basis function. The molecular orbital calculation was performed using widely used Gaussian 09 (Gaussian 09, Revision C. 01, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y. Honda, O. Kitao, H. Nakai, T. Vreven, J. A. Montgomery, Jr., J. E. Peralta, F. Ogliaro, M. Bearpark, J. J. Heyd, E. Brothers, K. N. Kudin, V. N. Staroverov, T. Keith, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford C T, 2010.)

In the present embodiment, the following compound was used as the second organic compound. The second organic compound in the present disclosure is not limited to the following.

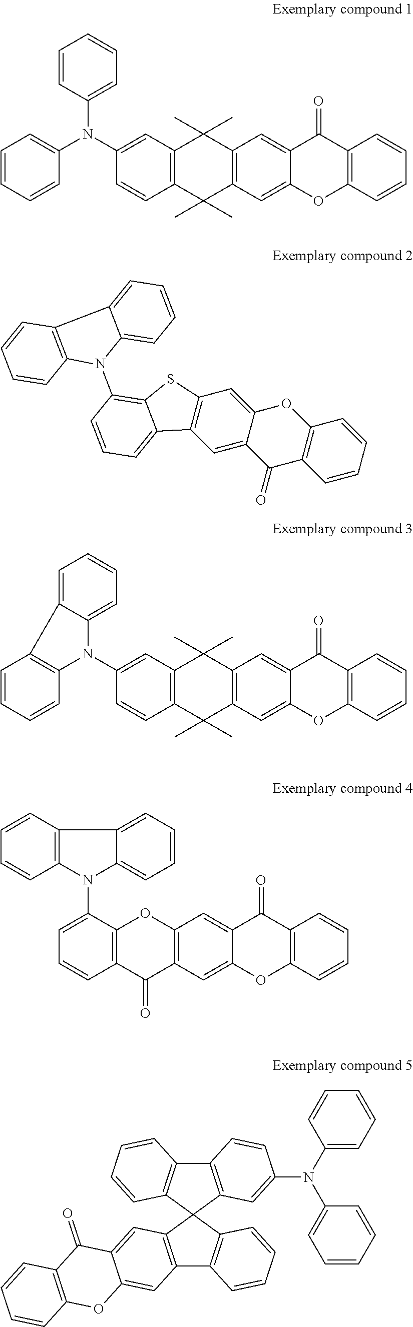 [SMILES: CC1(C)c2ccc(N(c3ccccc3)c3ccccc3)cc2C(C)(C)c2cc3c(=O)c4ccccc4oc3cc21 ; O=c1c2ccccc2oc2cc3sc4c(-n5c6ccccc6c6ccccc65)cccc4c3cc12 ; CC1(C)c2ccc(-n3c4ccccc4c4ccccc43)cc2C(C)(C)c2cc3c(=O)c4ccccc4oc3cc21 ; O=c1c2ccccc2oc2cc3c(=O)c4cccc(-n5c6ccccc6c6ccccc65)c4oc3cc12 ; O=c1c2ccccc2oc2cc3c(cc12)C1(c2ccccc2-c2ccc(N(c4ccccc4)c4ccccc4)cc21)c1ccccc1-3]

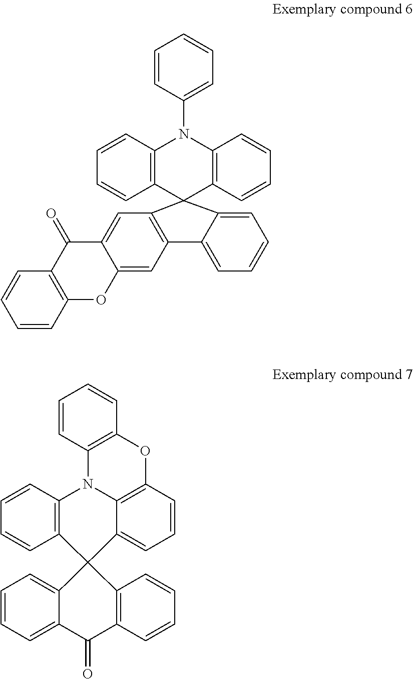 [SMILES: O=c1c2ccccc2oc2cc3c(cc12)C1(c2ccccc2-3)c2ccccc2N(c2ccccc2)c2ccccc21 ; O=C1c2ccccc2C2(c3ccccc31)c1ccccc1N1c3ccccc3Oc3cccc2c31]

Calculation results for Exemplary Compound 1 are described in detail below.

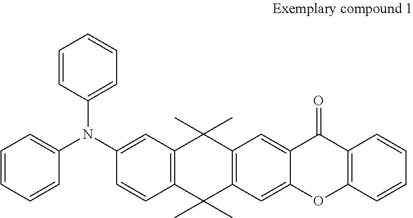 [SMILES: CC1(C)c2ccc(N(c3ccccc3)c3ccccc3)cc2C(C)(C)c2cc3c(=O)c4ccccc4oc3cc21]

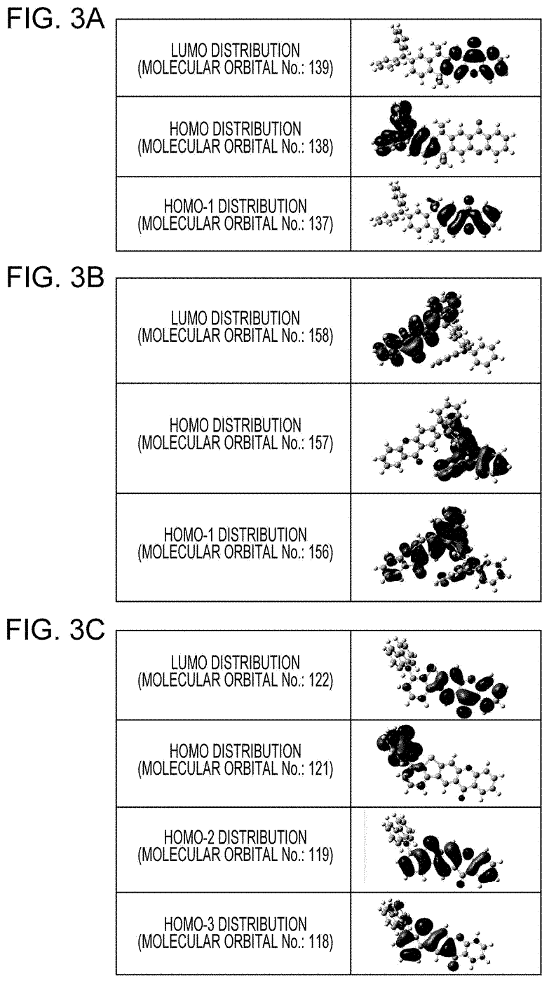

FIGS. 3A to 3C are diagrams of molecular orbitals of exemplary compounds. FIG. 3A is a diagram of LUMO, HOMO, and HOMO-1 orbital distributions of Exemplary Compound 1. It should be noted that the molecular orbital number indicates the number of the molecular orbital (MO), the total number of molecular orbitals depends on the type and number of atoms constituting the molecule, and therefore the molecular orbital numbers of the HOMO and LUMO are not determined uniquely.

Table 1 shows transitions between molecular orbitals of excited states of S₁ and T₂ for Exemplary Compound 1. Table 1 shows that the electronic transitions of the S₁ and T₂ states are transitions from different HOMOs to the same LUMO.

TABLE 1

| Excited | Molecular orbital No. of | Molecular orbital No. of |
|---|---|---|
| state | transition source | transition destination |
| S₁ | 138 | 139 |
| T₂ | 137 | 139 |
| | 129 | 139 |

For such characteristics, an acceptor unit can be a fused polycyclic structure with a carbonyl group or a xanthene structure. When the second organic compound has such an acceptor, a transition relationship as shown in Table 1 can be obtained. This relationship depends on the MO level of the acceptor relative to the MO level due to a unit constituting a donor. Exemplary Compound 1 has ΔE_{S1T1} of 0.01 eV, which is a small energy difference suitable for a compound that emits delayed fluorescence.

The second organic compound according to the present embodiment may have the following structure.

(1) The second organic compound cannot rotate due to orthogonal HOMO and LUMO.

(2) The second organic compound has HOMO and LUMO orbital distributions on a fused ring structure.

(1) is described below.

In the second organic compound according to the present embodiment, units constituting HOMO and LUMO planes of the molecular structure can be spatially orthogonal to each other. The HOMO and LUMO are composed of atoms with π electrons in the same plane and form HOMO and LUMO planes, respectively. The term “orthogonal”, as used herein, means that the HOMO plane and the LUMO plane form an angle of 90 degrees. In such a state, electronic transition involving charge transfer between the HOMO and LUMO occurs against local excitation with transition to a molecular orbital on each unit constituting the HOMO and LUMO. Due to the orthogonality, the exchange integral decreases significantly, and ΔE_{S1T1} also decreases.

An example of such a molecular structure is a spiro skeleton, which can be formed by substituting a donor substituent and an acceptor substituent to have an orthogonal relationship centered on spiro-fluorene or the like. Due to its high durability and heat resistance, the spiro-fluorene skeleton, if present, in the second organic compound contributes to improved reliability of the organic light-emitting element.

A specific example is Exemplary Compound 5.

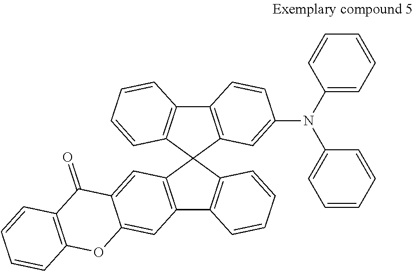 [SMILES: O=c1c2ccccc2oc2cc3c(cc12)C1(c2ccccc2-c2ccc(N(c4ccccc4)c4ccccc4)cc21)c1ccccc1-3]

FIG. 3B is a diagram of LUMO, HOMO, and HOMO-1 orbital distributions of Exemplary Compound 5.

Table 2 shows transitions between molecular orbitals of excited states of S₁ and T₂ for Exemplary Compound 5.

TABLE 2

| Excited | Molecular orbital No. of | Molecular orbital No. of |
|---|---|---|
| state | transition source | transition destination |
| S₁ | 157 | 158 |
| T₂ | 157 | 158 |
| | 156 | 158 |

Also in this compound, Exemplary Compound 5 has ΔE_{S1T1} of 0.01 eV, which is a small energy difference suitable for a compound that emits delayed fluorescence.

(2) is then described below.

The second organic compound can have HOMO and LUMO orbital distributions on a fused ring structure. The HOMO and LUMO orbital distributions on the fused ring structure can increase oscillator strength in electronic transition. This can enhance the ability to transfer excitation energy from the second organic compound to the third organic compound. In such a case, the HOMO and LUMO on the fused ring structure tend to overlap.

On the other hand, a delayed fluorescent material can have more widely separated HOMO and LUMO due to a smaller ΔE_{S1T1}. In other words, the HOMO and LUMO may not overlap. Thus, in the fused ring structure, a HOMO region overlapping the LUMO is preferably not more than half, more preferably 30% or less, of the LUMO. The overlap ratio may be determined by using a group of atoms forming both the HOMO and LUMO as a numerator and a group of atoms forming the LUMO as a denominator. A structure change by rotation is not possible in the fused ring, and a structure change in the excited state is prevented. This also increases the oscillator strength. An example of such a structure is Exemplary Compound 2.

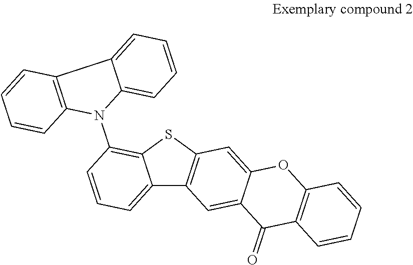 [SMILES: O=c1c2ccccc2oc2cc3sc4c(-n5c6ccccc6c6ccccc65)cccc4c3cc12]

FIG. 3C is a diagram of LUMO, HOMO, HOMO-2, and HOMO-3 orbital distributions of Exemplary Compound 2.

Table 3 shows transitions between molecular orbitals of excited states of S₁ and T₂ for Exemplary Compound 2.

TABLE 3

| Excited | Molecular orbital No. of | Molecular orbital No. of |
|---|---|---|
| state | transition source | transition destination |
| S₁ | 121 | 122 |
| T₂ | 119 | 122 |
| | 121 | 122 |
| | 118 | 123 |
| | 119 | 123 |

Also in Exemplary Compound 2, as in Exemplary Compound 1, a large difference between the spin-orbit coupling in S₁ and the spin-orbit coupling in T₁ improves the rate of reverse intersystem crossing. FIG. 3C shows that the aromatic ring unit in which both HOMO and LUMO are distributed cannot rotate with respect to the LUMO distribution plane. This reduces a molecular structure change and tends to increase the oscillator strength. Thus, the resulting organic compound can have a small ΔE_{S1T1} and non-zero oscillator strength. The calculated ΔE_{S1T1} is 0.26 eV.

The molecular structure of the second organic compound in the present disclosure is described below.

The second organic compound according to the present embodiment can be represented by the formula [1]:

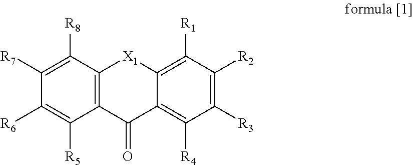

wherein R₁ to R₈ independently denote a hydrogen atom, a halogen atom, a substituted or unsubstituted alkyl group, a substituted or unsubstituted alkoxy group, a substituted or unsubstituted amino group, a substituted or unsubstituted aromatic hydrocarbon group, a substituted or unsubstituted heterocyclic group, a substituted or unsubstituted aryloxy group, a silyl group, or a cyano group.

At least adjacent two of R₁ to R₈ may be bonded together to form a ring structure. The ring structure may have a substituent.

Furthermore, any one of R₁ to R₈ in the formula [1] is a donor substituent. The term “donor substituent”, as used herein, refers to a substituted or unsubstituted amino group, and substituents on the amino group may be bonded together to form a ring structure.

X₁ denotes oxygen, sulfur, selenium, tellurium, or a CY₁Y₂ group. Y₁ and Y₂ independently denote a hydrogen atom, a halogen atom, a substituted or unsubstituted alkyl group, a substituted or unsubstituted alkoxy group, a substituted or unsubstituted amino group, a substituted or unsubstituted aryl group, a substituted or unsubstituted heterocyclic group, a substituted or unsubstituted aryloxy group, a silyl group, or a cyano group.

Examples of the halogen atom in R₁ to R₈ and Y₁and Y₂ include, but are not limited to, fluorine, chlorine, bromine, and iodine.

The alkyl group in R₁to R₈ and Y₁ and Y₂ may be an alkyl group having 1 to 10 carbon atoms. Specific examples include, but are not limited to, a methyl group, an ethyl group, a n-propyl group, an isopropyl group, a n-butyl group, a t-butyl group, a sec-butyl group, an octyl group, a cyclohexyl group, a 1-adamantyl group, and a 2-adamantyl group. A hydrogen of the alkyl group may be substituted with a halogen atom. In particular, a hydrogen of the alkyl group may be substituted with a fluorine atom. A hydrogen atom of the alkyl group may be a deuterium atom.

The alkoxy group in R₁ to R₈ and Y₁ and Y₂ may be an alkoxy group having 1 to 10 carbon atoms. Specific examples include, but are not limited to, a methoxy group, an ethoxy group, a propoxy group, a 2-ethyl-octyloxy group, and a benzyloxy group.

The amino group in R₁ to R₈ and Y₁ and Y₂ may be an amino group having an alkyl group, an aryl group, or a heterocyclic group as a substituent. Specific examples include, but are not limited to, an N-methylamino group, an N-ethylamino group, an N,N-dimethylamino group, an N,N-diethylamino group, an N-methyl-N-ethylamino group, an N-benzylamino group, an N-methyl-N-benzylamino group, an N,N-dibenzylamino group, an anilino group, an N,N-diphenylamino group, an N,N-dinaphthylamino group, an N,N-difluorenylamino group, an N-phenyl-N-tolylamino group, an N,N-ditolylamino group, an N-methyl-N-phenylamino group, an N,N-dianisolylamino group, an N-mesityl-N-phenylamino group, an N,N-dimesitylamino group, an N-phenyl-N-(4-t-butylphenyl)amino group, an N-phenyl-N-(4-trifluoromethylphenyl)amino group, an N-piperidyl group, a carbazolyl group, and an acridyl group.

The aryl group in R₁ to R₈ and Y₁ and Y₂ may be an aryl group having 6 to 60 carbon atoms. Specific examples include, but are not limited to, a phenyl group, a naphthyl group, an indenyl group, a biphenyl group, a terphenyl group, a fluorenyl group, a phenanthryl group, a triphenylenyl group, a pyrenyl group, an anthranyl group, a perylenyl group, a chrysenyl group, and a fluoranthenyl group.

The heterocyclic group in R₁ to R₈ and Y₁ and Y₂ may be a heterocyclic group having 3 to 59 carbon atoms. Specific examples include, but are not limited to, a pyridyl group, a pyrimidyl group, a pyrazyl group, a triazyl group, a benzofuranyl group, a benzothiophenyl group, a dibenzofuranyl group, a dibenzothiophenyl group, an oxazolyl group, an oxadiazolyl group, a thiazolyl group, a thiadiazolyl group, a carbazolyl group, an acridinyl group, and a phenanthrolyl group.

Examples of the aryloxy group in R₁ to R₈ and Y₁ and Y₂ include, but are not limited to, a phenoxy group and a thienyloxy group.

Examples of the silyl group in R₁ to R₈ and Y₁ and Y₂ include, but are not limited to, a trimethylsilyl group and a triphenylsilyl group.

Examples of optional substituents of the alkyl group, the alkoxy group, the amino group, the aryl group, the heterocyclic group, and the aryloxy group include, but are not limited to, alkyl groups, such as a methyl group, an ethyl group, a n-propyl group, an isopropyl group, a n-butyl group, and a t-butyl group; aralkyl groups, such as a benzyl group; aryl groups, such as a phenyl group and a biphenyl group; heterocyclic groups, such as a pyridyl group and a pyrrolyl group; amino groups, such as a dimethylamino group, a diethylamino group, a dibenzylamino group, a diphenylamino group, and a ditolylamino group; alkoxy groups, such as a methoxy group, an ethoxy group, and a propoxy group; aryloxy groups, such as a phenoxy group; halogen atoms, such as fluorine, chlorine, bromine, and iodine; and a cyano group.

The ring structure formed by adjacent two of R₁ to R₈ may be an aromatic ring, an alicyclic ring, or a heterocyclic ring. The number of rings is not particularly limited. In particular, the ring structure can be an aromatic ring, and three or less rings may be formed. Formation of two rings means that formation of two rings in a benzene ring forms a three ring structure, such as an anthracene ring.

The ring structure formed by adjacent two of R₁ to R₈ may have a substituent, which may be, but is not limited to, an alkyl group, such as a methyl group, an ethyl group, a n-propyl group, an isopropyl group, a n-butyl group, or a t-butyl group; an aralkyl group, such as a benzyl group; an aryl group, such as a phenyl group or a biphenyl group; a heterocyclic group, such as a pyridyl group or a pyrrolyl group; an amino group, such as a dimethylamino group, a diethylamino group, a dibenzylamino group, a diphenylamino group, or a ditolylamino group; an alkoxy group, such as a methoxy group, an ethoxy group, or a propoxy group; an aryloxy group, such as a phenoxy group; a halogen atom, such as fluorine, chlorine, bromine, or iodine; or a cyano group.

The second organic compound with the above structure may be a compound composed of a donor site and an acceptor site with a carbonyl group. Formation of a ring structure via another aromatic ring at the acceptor site with a carbonyl group broadens the LUMO orbital and contributes to an increase in oscillator strength. An increase in oscillator strength results in an increase in the rate of energy transfer to a light-emitting material and therefore contributes to the improvement in the efficiency of the organic light-emitting element. Furthermore, the molecular structure has high planarity, and the LUMO orbital spreads. These also contribute to the improvement of the electron-transport characteristics.

The substitution position of the donor substituent is not particularly limited but can be bonded to an aromatic ring unit cross-linked to the acceptor site with a carbonyl group. This contributes to a decrease in the exchange integral due to the separation of the HOMO and LUMO and contributes to an increase in oscillator strength because the HOMO and LUMO overlap cannot cause a structure change, such as rotation, in the excited state. This is because a cross-link+an aromatic ring unit serve as a spacer for the acceptor site with a carbonyl group and as a bridge between the HOMO and LUMO, which results in an organic compound with a smallΔE_{S1T1} and non-zero oscillator strength. This enables the second organic compound to perform efficient conversion from T₁ to S₁ and Forster energy transfer and particularly contributes to the improvement in the luminescence efficiency of the organic light-emitting element. The donor substituent is a substituted or unsubstituted amino group, and substituents on the amino group may be cross-linked together.

A cross-linked structure for the xanthene structure may not contain an Sp3-hybridized nitrogen atom. This is because the electron-donating properties of the nitrogen atom directly contribute to the acceptor site with a carbonyl group, so that the overlap between the HOMO and LUMO is too large to provide a small ΔE_{S1T1} required for a delayed fluorescent material.

An amino group or an unsubstituted amino group serving as a donor substituent may have the following structure:

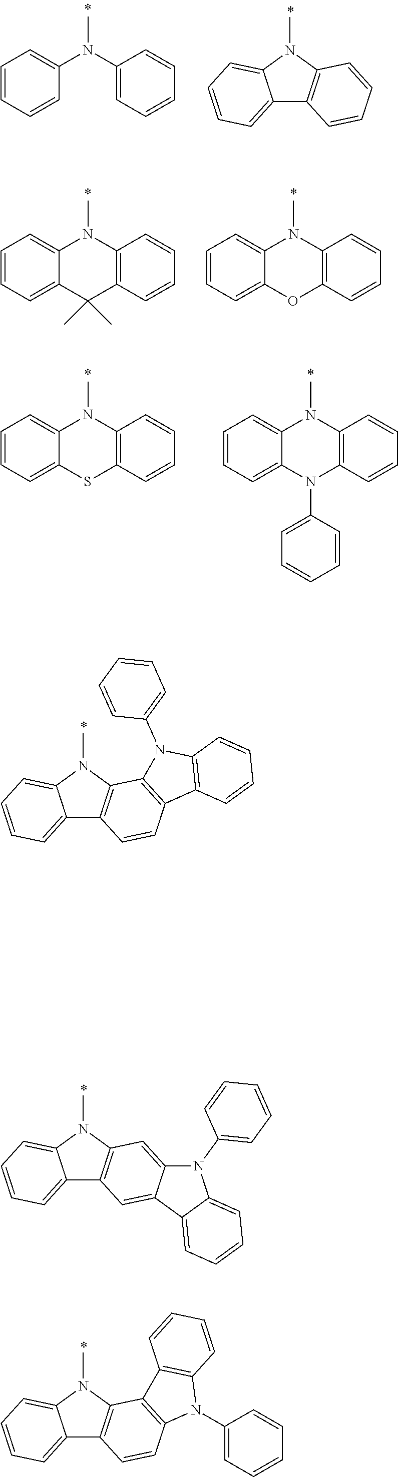

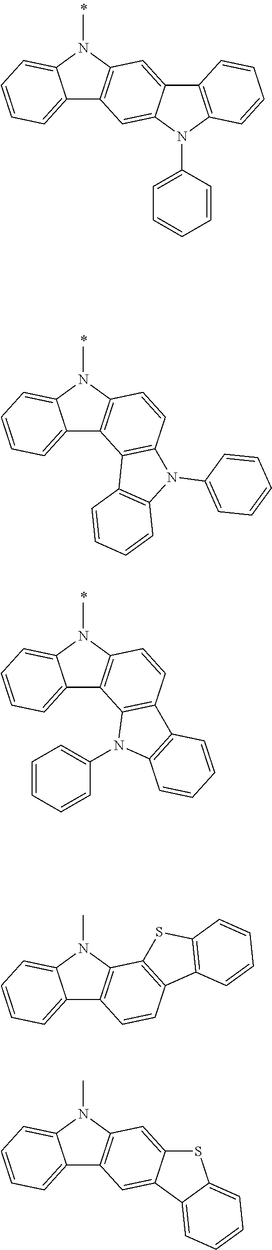 [SMILES: Cn1c2ccccc2c2cc3c(cc21)c1ccccc1n3-c1ccccc1 ; Cn1c2ccccc2c2c3c4ccccc4n(-c4ccccc4)c3ccc21 ; Cn1c2ccccc2c2c1ccc1c3ccccc3n(-c3ccccc3)c12 ; Cn1c2ccccc2c2ccc3c4ccccc4sc3c21 ; Cn1c2ccccc2c2cc3c(cc21)sc1ccccc13]

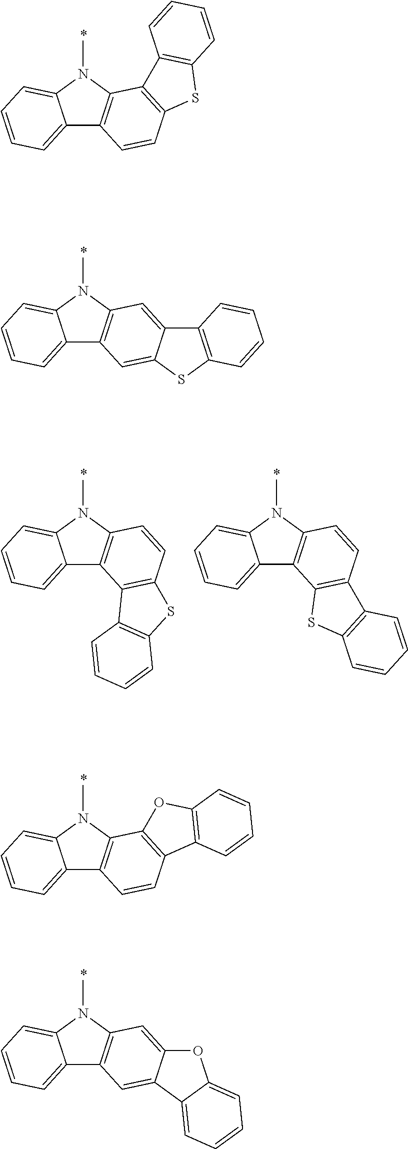

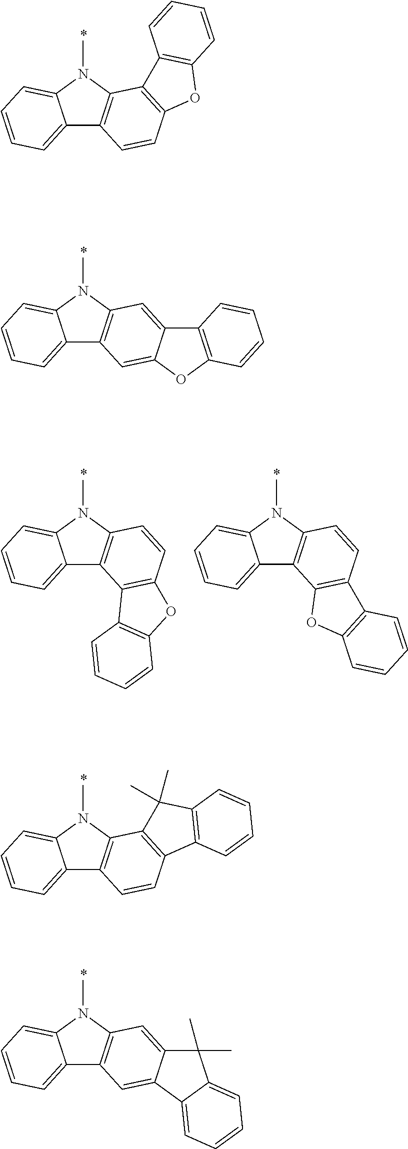

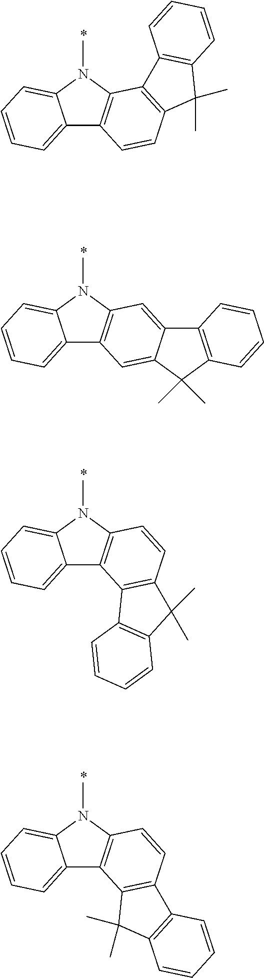 [SMILES: Cn1c2ccccc2c2ccc3c(c21)-c1ccccc1C3(C)C ; Cn1c2ccccc2c2cc3c(cc21)-c1ccccc1C3(C)C ; Cn1c2ccccc2c2c3c(ccc21)C(C)(C)c1ccccc1-3 ; Cn1c2ccccc2c2c3c(ccc21)-c1ccccc1C3(C)C]

wherein * denotes a binding position. The amino group may have a substituent, which is selected from a methyl group, an ethyl group, a n-propyl group, an isopropyl group, a n-butyl group, a t-butyl group, a phenyl group, a biphenyl group, a naphthyl group, a pyridyl group, a pyrazyl group, a triazyl group, a dimethylamino group, a diethylamino group, a dibenzylamino group, a diphenylamino group, a ditolylamino group, a methoxy group, an ethoxy group, a propoxy group, a phenoxy group, fluorine, chlorine, bromine, iodine, and a cyano group.

The second organic compound according to the present embodiment can satisfy the following to improve drive durability.

(3) The second organic compound is a delayed fluorescent material without a rotatable single bond connecting aryl groups.

This can provide an organic light-emitting element having not only high luminescence efficiency but also a long drive lifetime.

(3) is described below.

In the second organic compound according to the present embodiment, a single bond connecting aryl groups may not rotate from the perspective of luminescence efficiency and drive lifetime. This means that aryl groups are bonded together by a plurality of single bonds. One example is Exemplary Compound 7.

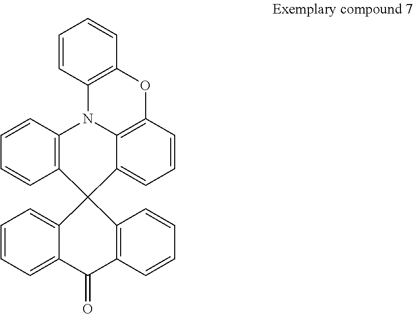 [SMILES: O=C1c2ccccc2C2(c3ccccc31)c1ccccc1N1c3ccccc3Oc3cccc2c31]

Exemplary Compound 7 has ΔE_{S1T1} due to the orthogonality between the HOMO and LUMO by the spiro structure and has a non-rotatable single bond connecting aryl groups. Thus, even when a single bond between aryl groups is cleaved, the aryl groups are bonded by another single bond and are easily recombined. Thus, the resulting organic light-emitting element has a long drive lifetime.

An organic compound with a spiro skeleton in its molecular structure is difficult to crystallize and has a high glass transition temperature. Thus, the second organic compound can have a spiro skeleton.

Although some requirements for the second organic compound have been described, in the present disclosure, the first organic compound may be a material that satisfies the requirements for the second organic compound. In such a case, the first organic compound can be a material with a higher S₁ energy level and a higher T₁ energy level.

Energy transfer to a light-emitting dopant is mainly of the Forster type. Thus, an absorption spectrum of a light-emitting material can at least partially overlap an emission spectrum of the second organic compound.

Other specific examples of an organic compound according to the present disclosure are described below. However, the present disclosure is not limited to these examples.

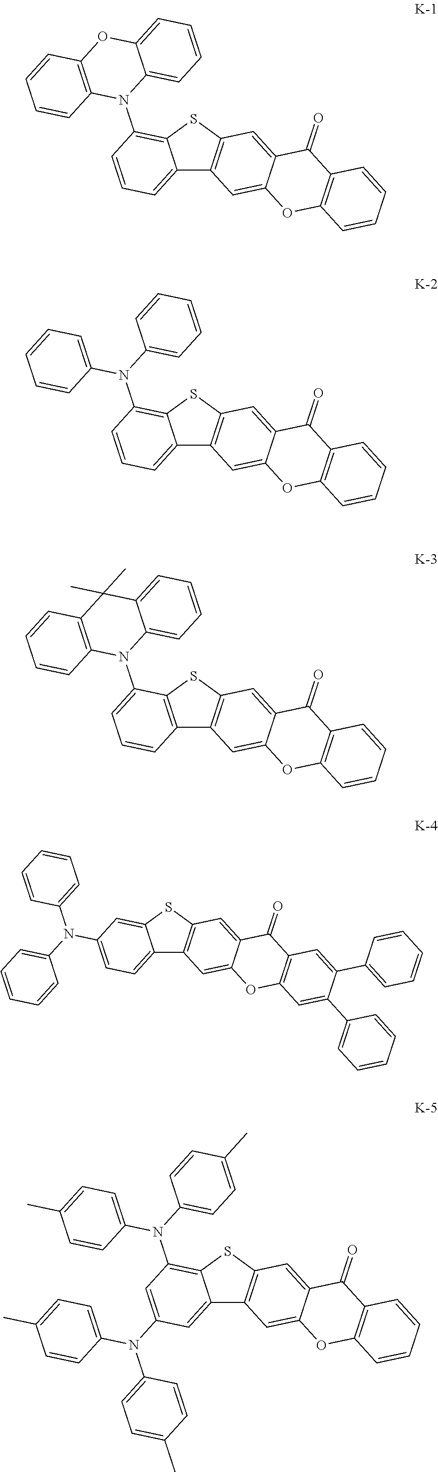 [SMILES: O=c1c2ccccc2oc2cc3c(cc12)sc1c(N2c4ccccc4Oc4ccccc42)cccc13 ; O=c1c2ccccc2oc2cc3c(cc12)sc1c(N(c2ccccc2)c2ccccc2)cccc13 ; CC1(C)c2ccccc2N(c2cccc3c2sc2cc4c(=O)c5ccccc5oc4cc23)c2ccccc21 ; O=c1c2cc(-c3ccccc3)c(-c3ccccc3)cc2oc2cc3c(cc12)sc1cc(N(c2ccccc2)c2ccccc2)ccc13 ; Cc1ccc(N(c2ccc(C)cc2)c2cc(N(c3ccc(C)cc3)c3ccc(C)cc3)c3sc4cc5c(=O)c6ccccc6oc5cc4c3c2)cc1]

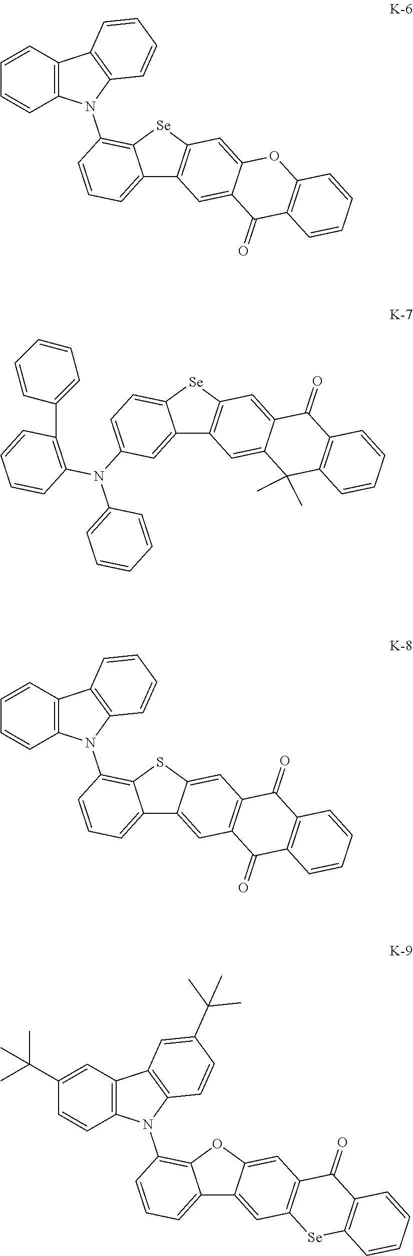 [SMILES: O=c1c2ccccc2oc2cc3[se]c4c(-n5c6ccccc6c6ccccc65)cccc4c3cc12 ; CC1(C)c2ccccc2C(=O)c2cc3[se]c4ccc(N(c5ccccc5)c5ccccc5-c5ccccc5)cc4c3cc21 ; O=C1c2ccccc2C(=O)c2cc3c(cc21)sc1c(-n2c4ccccc4c4ccccc42)cccc13 ; CC(C)(C)c1ccc2c(c1)c1cc(C(C)(C)C)ccc1n2-c1cccc2c1oc1cc3c(=O)c4ccccc4[se]c3cc12]

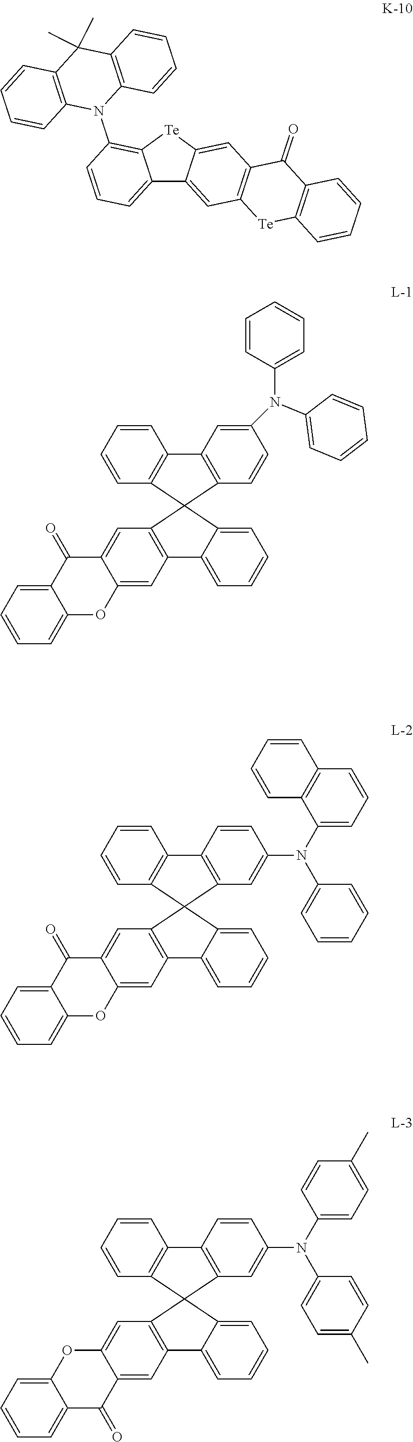

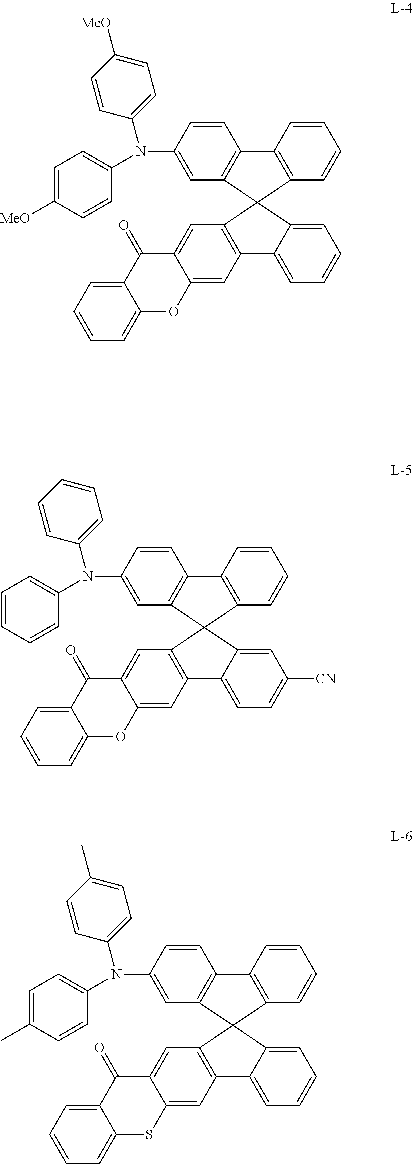 [SMILES: COc1ccc(N(c2ccc(OC)cc2)c2ccc3c(c2)C2(c4ccccc4-3)c3ccccc3-c3cc4oc5ccccc5c(=O)c4cc32)cc1 ; N#Cc1ccc2c(c1)C1(c3ccccc3-c3ccc(N(c4ccccc4)c4ccccc4)cc31)c1cc3c(=O)c4ccccc4oc3cc1-2 ; Cc1ccc(N(c2ccc(C)cc2)c2ccc3c(c2)C2(c4ccccc4-3)c3ccccc3-c3cc4sc5ccccc5c(=O)c4cc32)cc1]

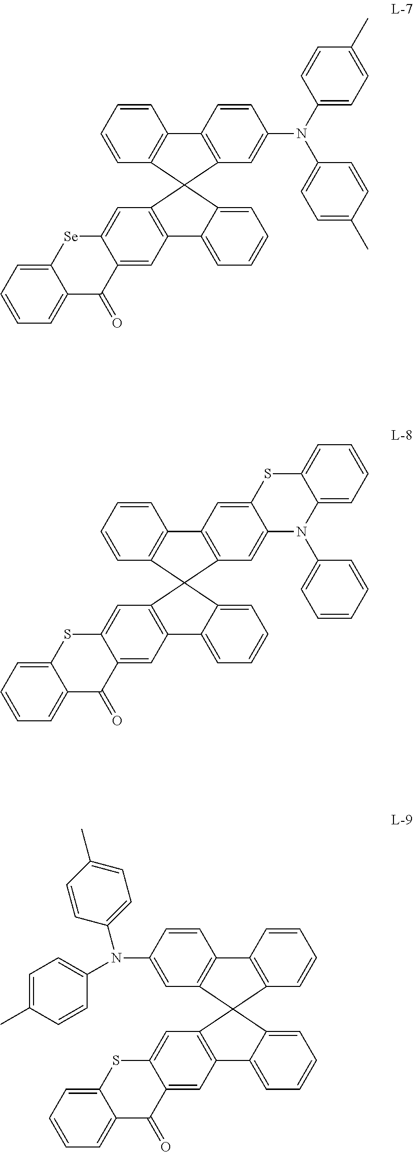

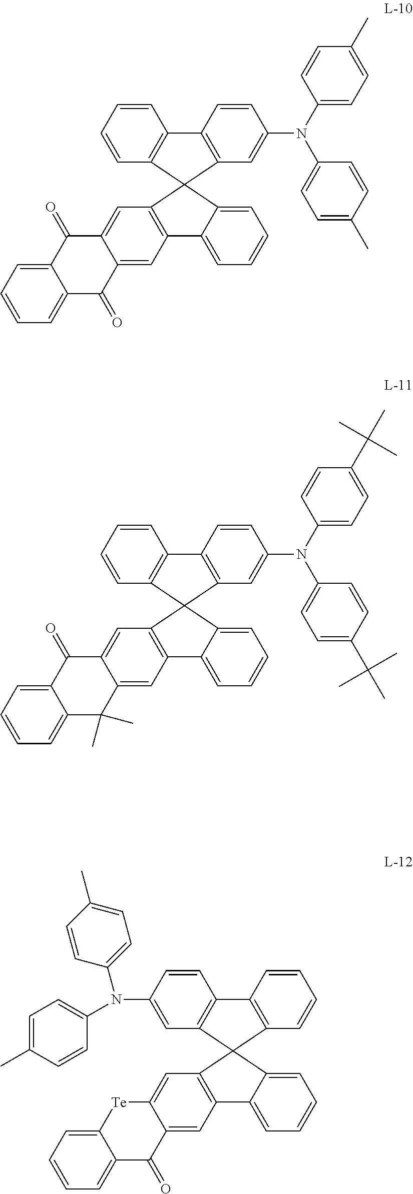

Next, the organic light-emitting element according to the present embodiment is described below. The organic light-emitting element according to the present embodiment includes at least a first electrode, a second electrode, and an organic compound layer between these electrodes. One of the first electrode and the second electrode is a positive electrode, and the other is a negative electrode. In the organic light-emitting element according to the present embodiment, the organic compound layer may be a single layer or a laminate of a plurality of layers, provided that the organic compound layer has a light-emitting layer. When the organic compound layer is a laminate of a plurality of layers, the organic compound layer may have a hole-injection layer, a hole-transport layer, an electron-blocking layer, a hole/exciton-blocking layer, an electron-transport layer, and/or an electron-injection layer, in addition to the light-emitting layer. The light-emitting layer may be a single layer or a laminate of a plurality of layers.

In the organic light-emitting element according to the present embodiment, when the plurality of layers are light-emitting layers, a light-emitting layer different from the light-emitting layer including the first organic compound, the second organic compound, and the third organic compound according to the present embodiment may be a layer composed only of the organic compound according to the present embodiment or may be composed of a host and a guest. The host is the compound with the highest mass ratio among the compounds constituting the light-emitting layer. The guest is a compound that has a lower mass ratio than the host among the compounds constituting the light-emitting layer and that is a principal light-emitting compound. The assist material is a compound that has a lower mass ratio than the host among the compounds constituting the light-emitting layer and that assists the guest in emitting light. The assist material is also referred to as a second host. The host material may also be referred to as a first compound, and the assist material may also be referred to as a second compound.

When the organic compound according to the present embodiment is used as a guest of the light-emitting layer, the concentration of the guest preferably ranges from 0.01% to 20% by weight, more preferably 0.1% to 10% by weight, of the entire light-emitting layer.

The light-emitting layer according to the present embodiment may have any emission color. The emission color may be mixed with the emission color of another light-emitting layer. The mixture may produce white color emission. The term “plurality of layers”, as used herein, refers to a laminate of the light-emitting layer and another light-emitting layer. For white color emission, another light-emitting layer emits light of a color other than red, such as blue or green. More specifically, light of a color complementary to the emission color of one light-emitting layer may be emitted by another light-emitting layer. The other light-emitting layer is not limited to one layer. Such a layer is formed by vapor deposition or coating. This is described in detail below in exemplary embodiments.

When the light-emitting layer according to the present embodiment has a second light-emitting layer, the second light-emitting layer may have a fourth organic compound with lowest excited singlet energy equal to or lower than the lowest excited singlet energy of the first organic compound, a fifth organic compound that has lower lowest excited singlet energy than the fourth organic compound and is a delayed fluorescent material, and a sixth organic compound with lower lowest excited singlet energy than the fifth organic compound and the third organic compound. At least one of the exposed surface area of a single bond in the structure of the fourth organic compound and the exposed surface area of a single bond in the structure of the fifth organic compound is preferably 91 or more. Both of the exposed surface areas can be 91 or more. At least one of the exposed surface areas can be 100 or more, and both of the exposed surface areas can be 100 or more.

The organic light-emitting element according to the present embodiment may be used in combination with a known low- or high-molecular-weight hole-injection compound or hole-transport compound, host compound, light-emitting compound, electron-injection compound, or electron-transport compound. Examples of these compounds are described below.

The hole-injection or hole-transport material can be a material that can facilitate the injection of holes from a positive electrode and that has high hole mobility to transport the injected holes to a light-emitting layer. To prevent degradation of film quality, such as crystallization, in the organic light-emitting element, a material with a high glass transition temperature can be used. Examples of the low-molecular-weight or high-molecular-weight material with hole injection transport ability include, but are not limited to, triarylamine derivatives, aryl carbazole derivatives, phenylenediamine derivatives, stilbene derivatives, phthalocyanine derivatives, porphyrin derivatives, polyvinylcarbazole, polythiophene, and other electrically conductive polymers. The hole-injection or hole-transport material is also suitable for an electron-blocking layer. Specific examples of compounds that can be used as the hole-injection or hole-transport material are described below. As a matter of course, the present disclosure is not limited to these compounds.

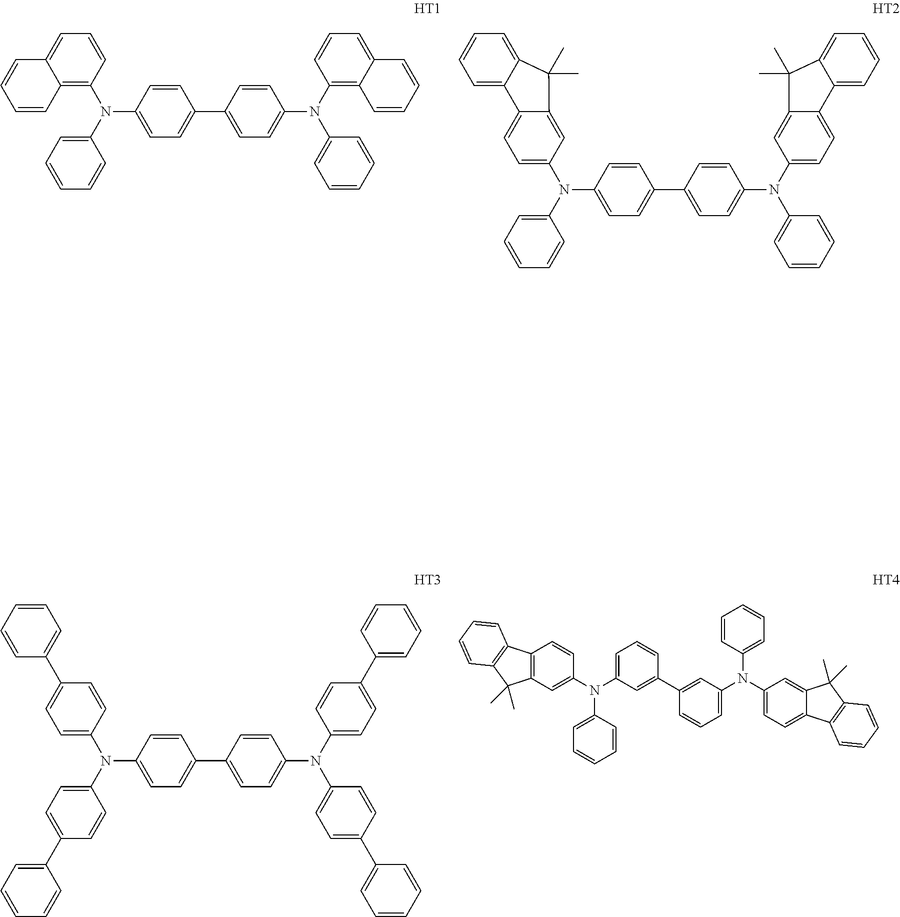

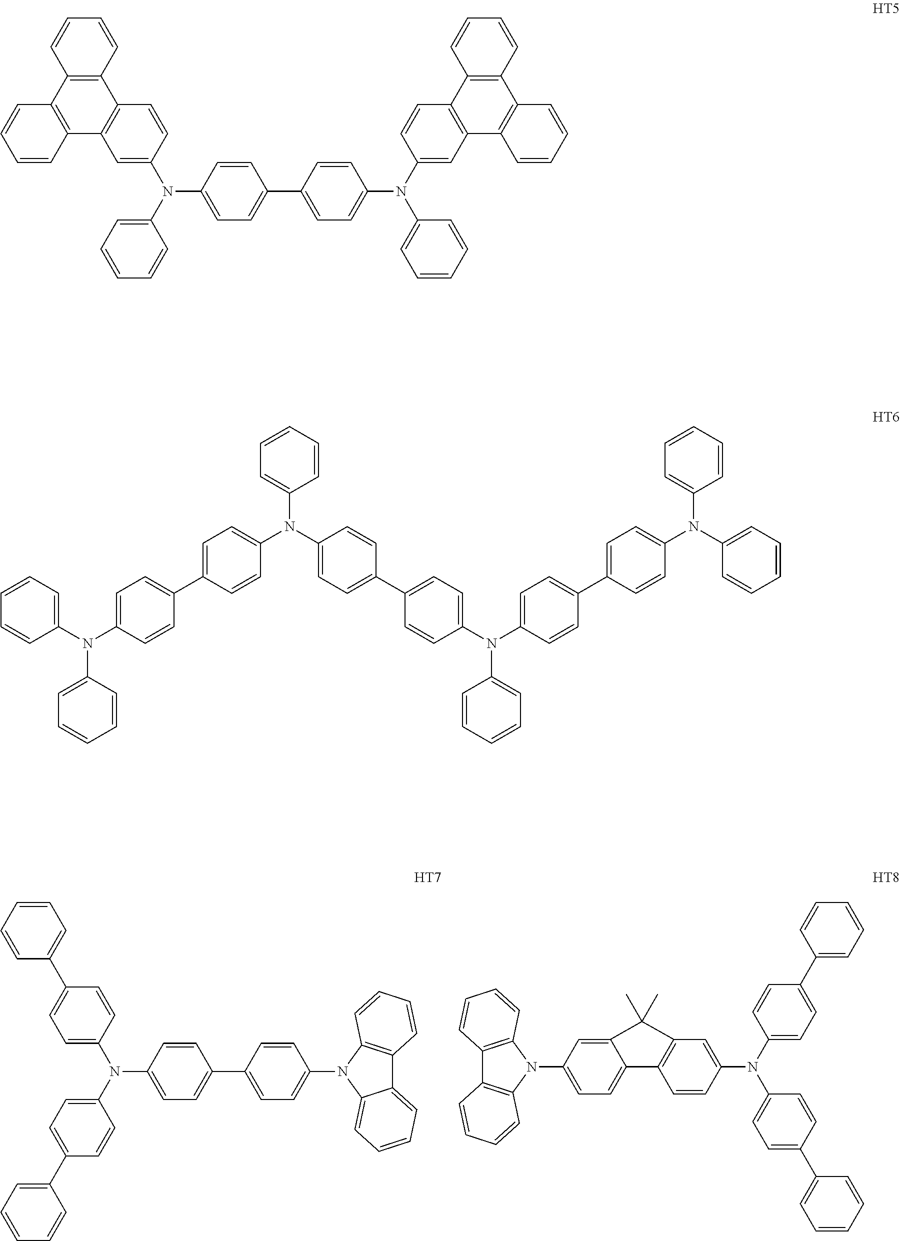

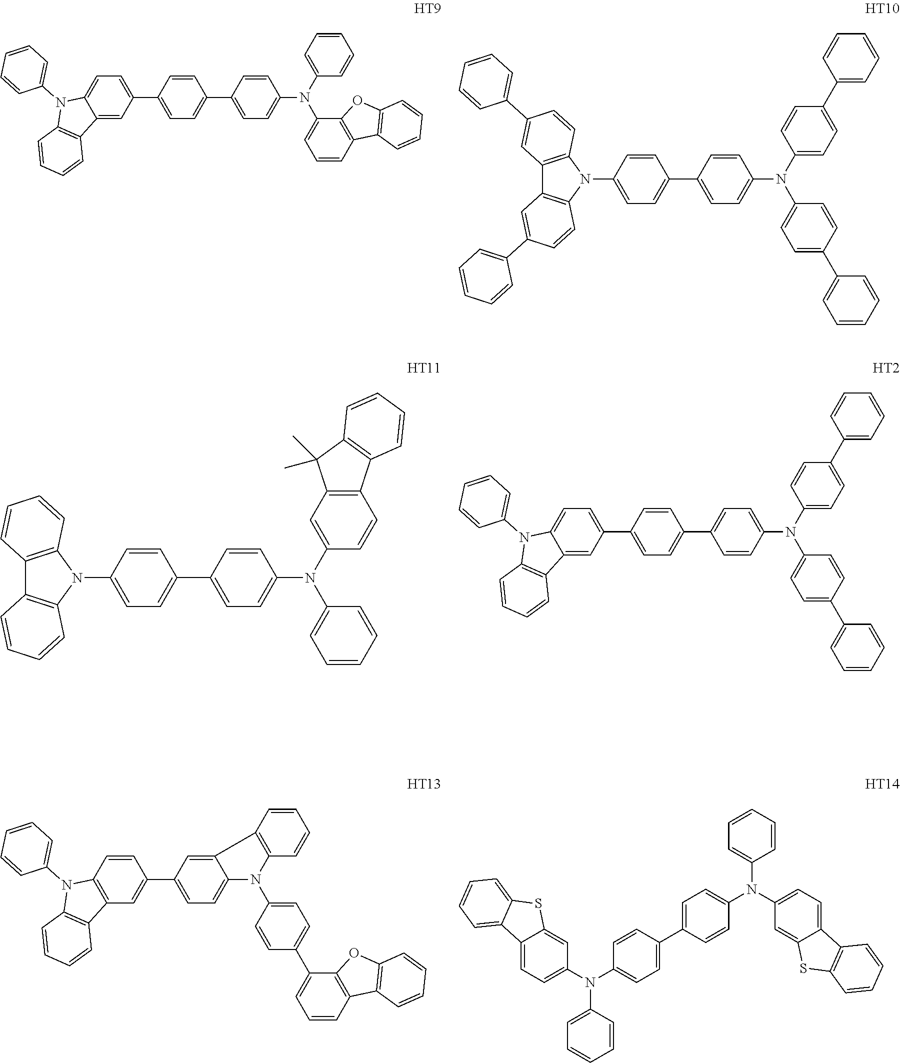

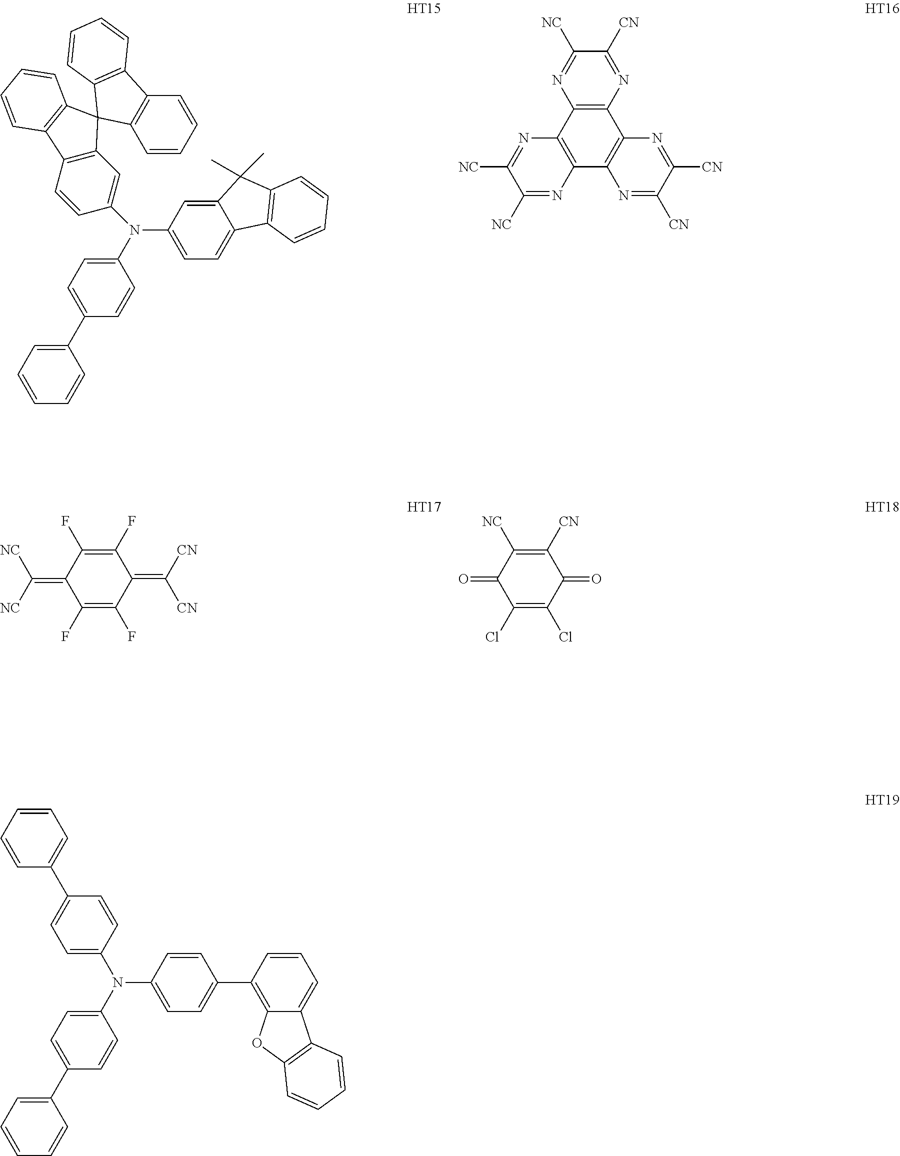 [SMILES: CC1(C)c2ccccc2-c2ccc(N(c3ccc(-c4ccccc4)cc3)c3ccc4c(c3)C3(c5ccccc5-c5ccccc53)c3ccccc3-4)cc21 ; N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F ; N#CC1=C(C#N)C(=O)C(Cl)=C(Cl)C1=O ; c1ccc(-c2ccc(N(c3ccc(-c4ccccc4)cc3)c3ccc(-c4cccc5c4oc4ccccc45)cc3)cc2)cc1]

Among these hole-transport materials, HT16 to HT18 can be used in a layer in contact with the positive electrode to decrease drive voltage. HT16 is widely used for organic light-emitting elements. HT2, HT3, HT4, HT5, HT6, HT10, and HT12 may be used for an organic compound layer adjacent to HT16. Furthermore, a plurality of materials may be used for one organic compound layer.

Examples of light-emitting materials mainly related to the light-emitting function include fused-ring compounds (for example, fluorene derivatives, naphthalene derivatives, pyrene derivatives, perylene derivatives, tetracene derivatives, anthracene derivatives, rubrene, etc.), quinacridone derivatives, coumarin derivatives, stilbene derivatives, organoaluminum complexes, such as tris(8-quinolinolato) aluminum, iridium complexes, platinum complexes, rhenium complexes, copper complexes, europium complexes, ruthenium complexes, and polymer derivatives, such as poly(phenylene vinylene) derivatives, polyfluorene derivatives, and polyphenylene derivatives.

Specific examples of compounds that can be used as light-emitting materials are described below. As a matter of course, the present disclosure is not limited to these compounds.

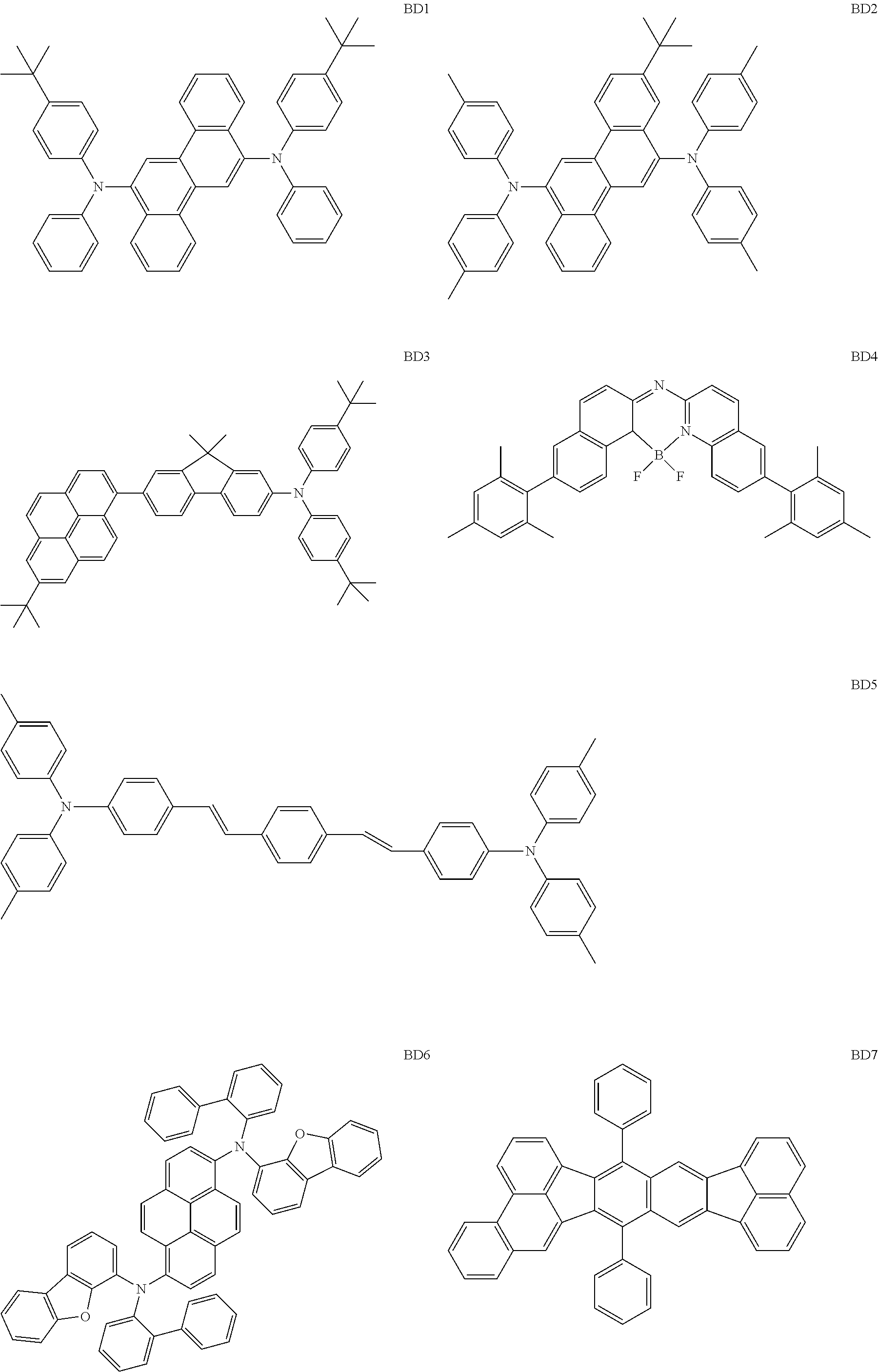

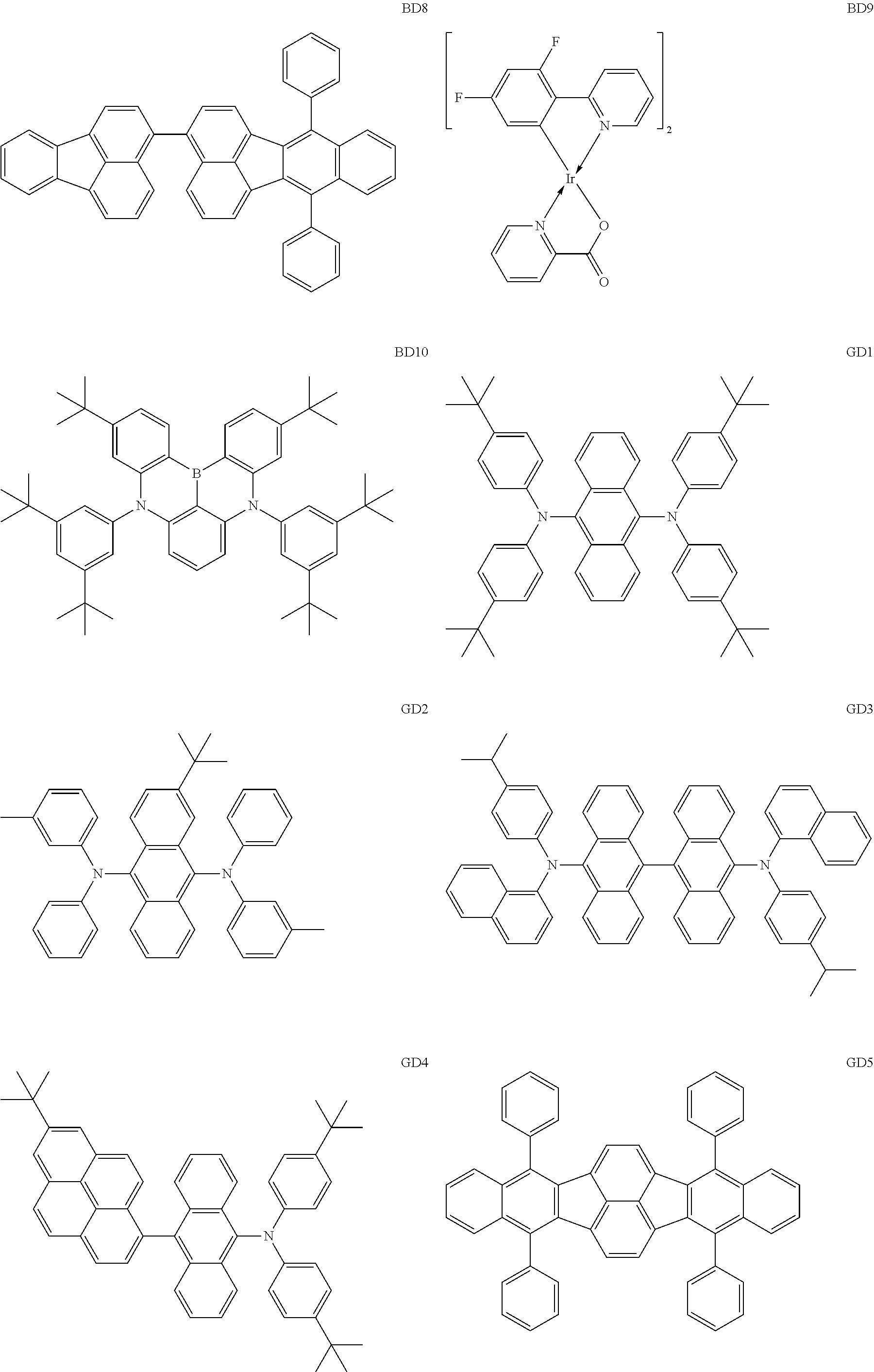

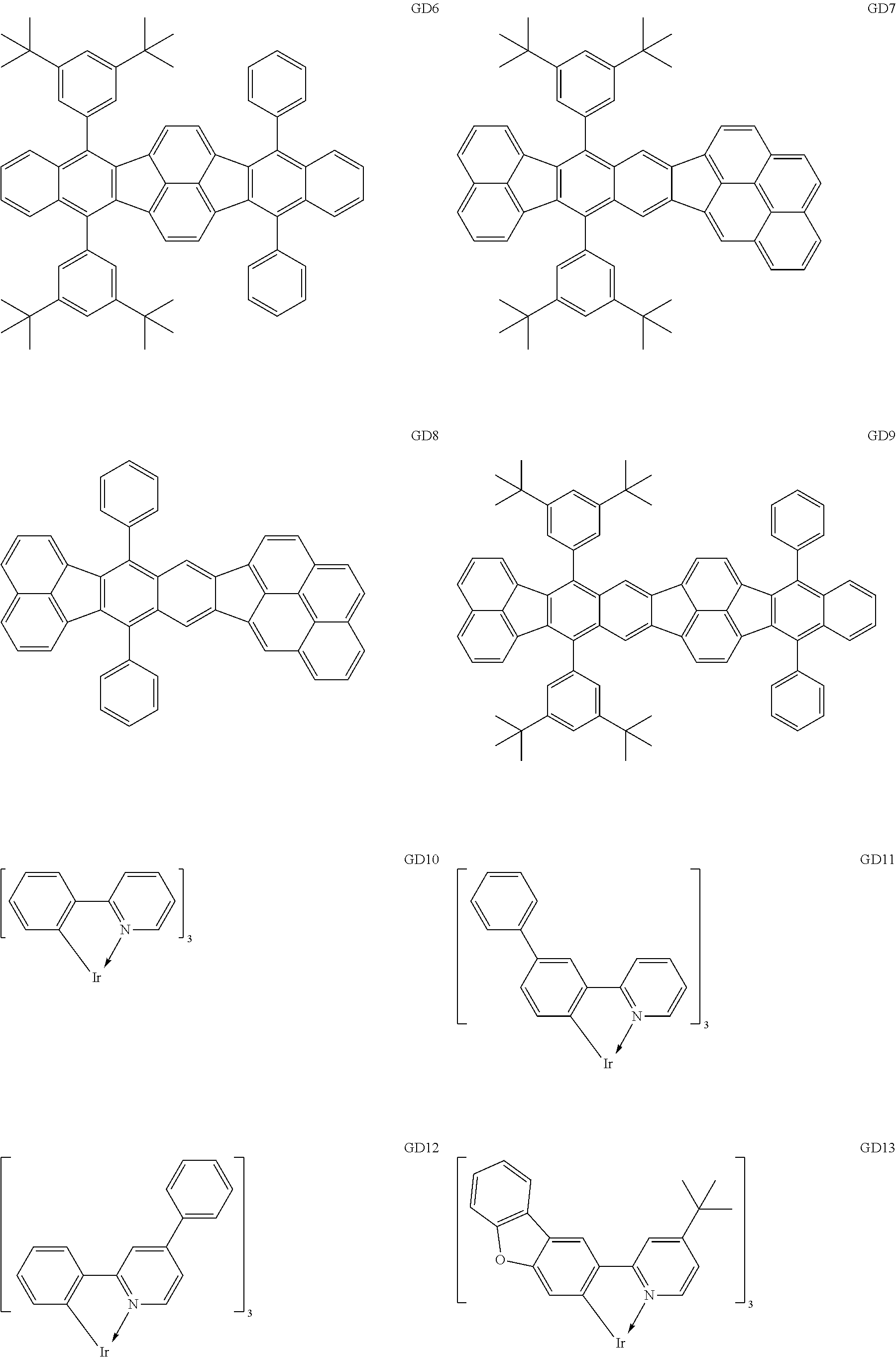

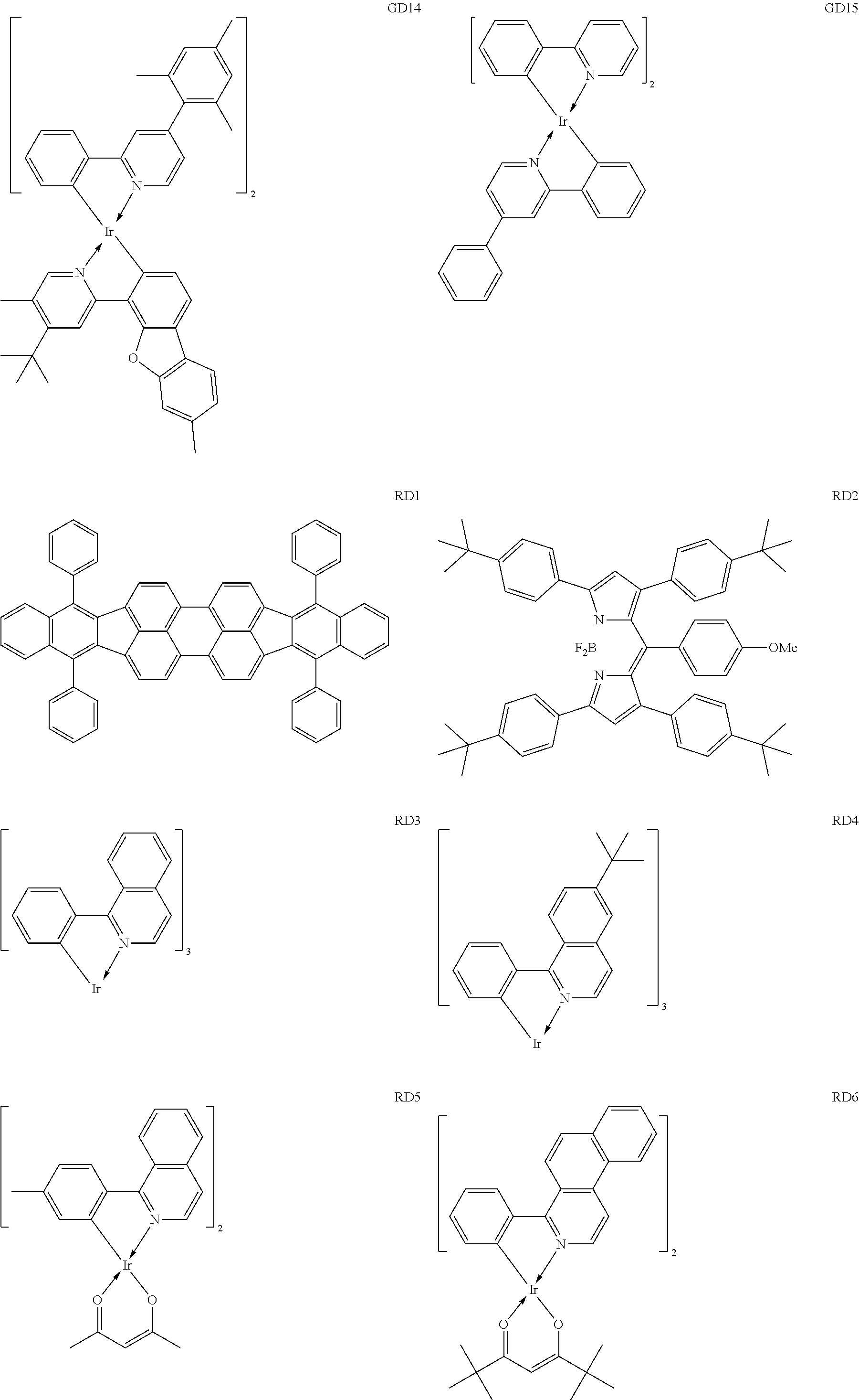

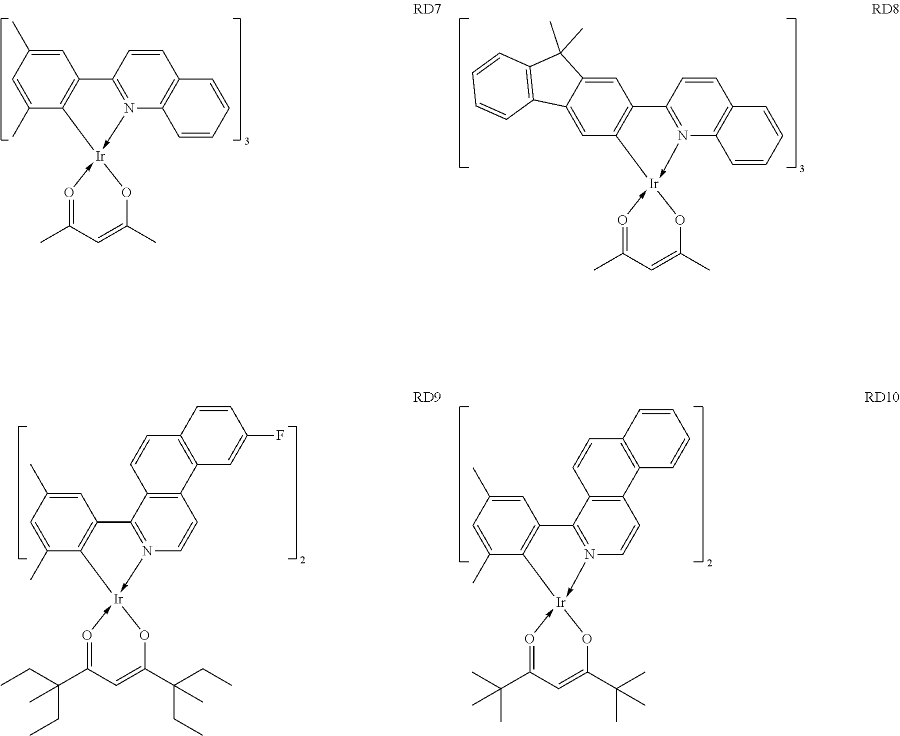

The light-emitting material can be a hydrocarbon compound. This is because a hydrocarbon compound can reduce a decrease in luminescence efficiency due to the formation of an exciplex and a decrease in color purity due to a change in an emission spectrum.

A hydrocarbon compound is a compound composed only of carbon and hydrogen. Exemplary compounds of a hydrocarbon compound are BD7, BD8, GD5 to GD9, and RD1.

The light-emitting material can be a fused polycyclic ring containing a five-membered ring. This is because a fused polycyclic ring containing a five-membered ring is highly stable against oxidation due to its high ionization potential. Exemplary compounds of a fused polycyclic ring containing a five-membered ring are BD7, BD8, GD5 to GD9, and RD1.

Examples of a light-emitting layer host or a light-emitting assist material in the light-emitting layer include aromatic hydrocarbon compounds and derivatives thereof, carbazole derivatives, dibenzofuran derivatives, dibenzothiophene derivatives, organoaluminum complexes, such as tris(8-quinolinolato) aluminum, and organic beryllium complexes.

Specific examples of a compound used as a light-emitting layer host or a light-emitting assist material in the light-emitting layer are described below. However, as a matter of course, the present disclosure is not limited to these examples.

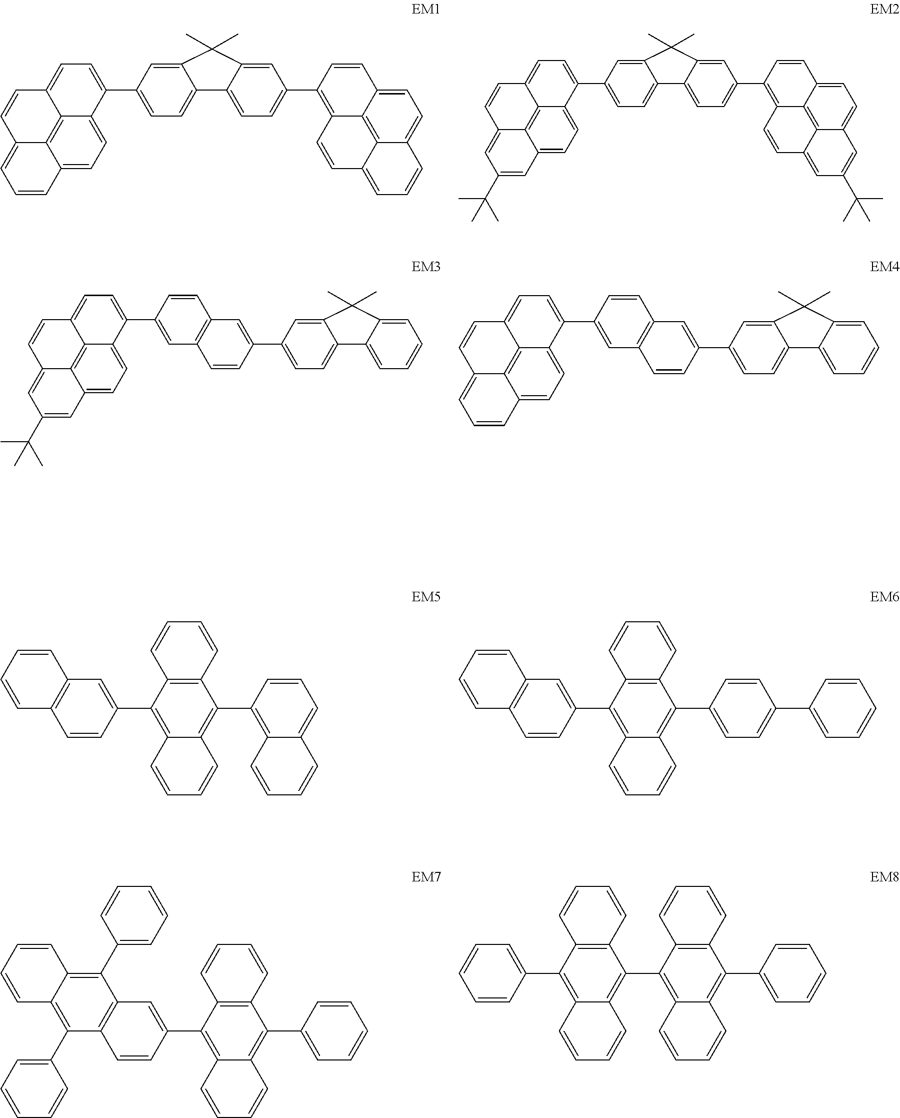

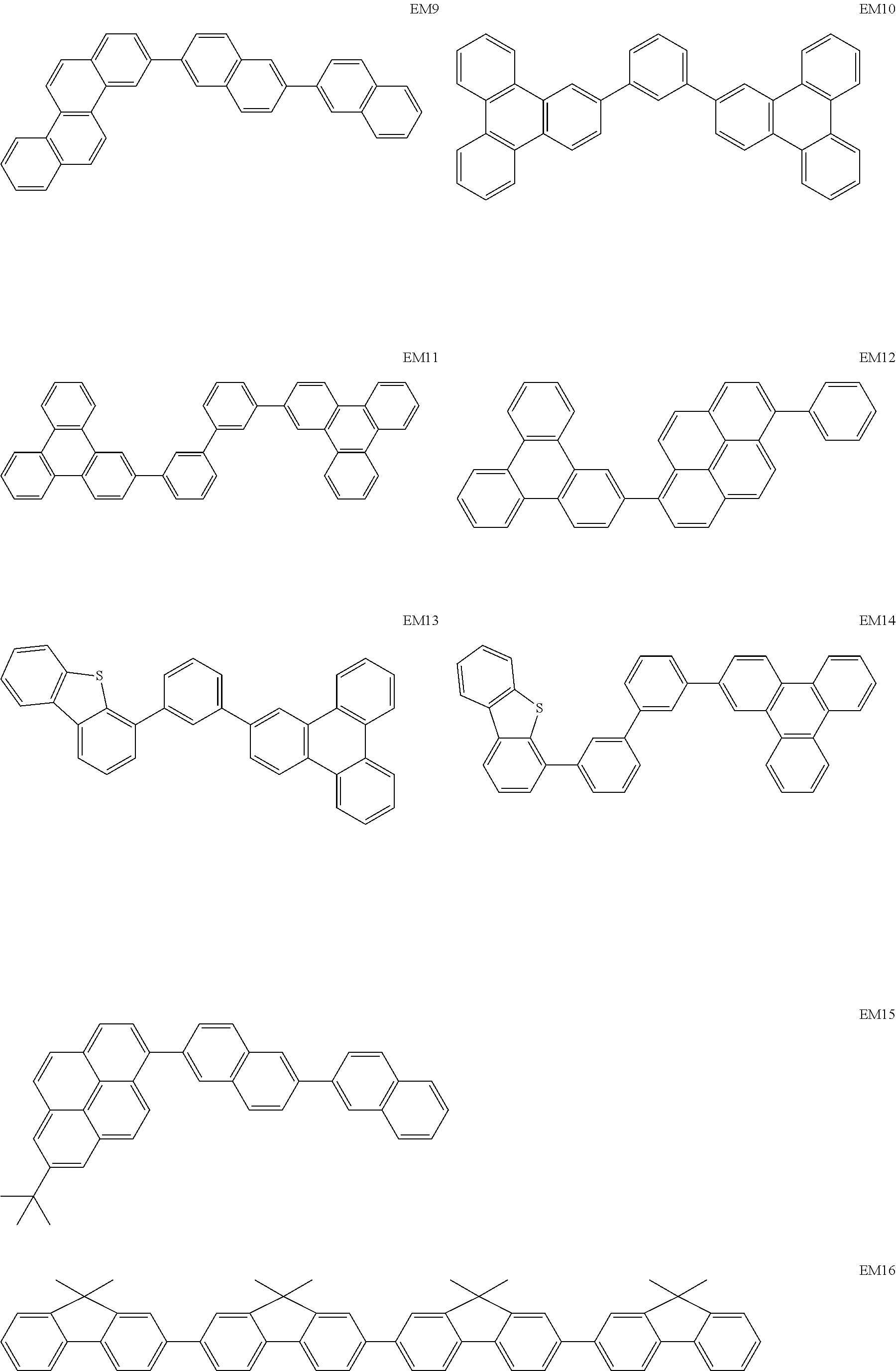

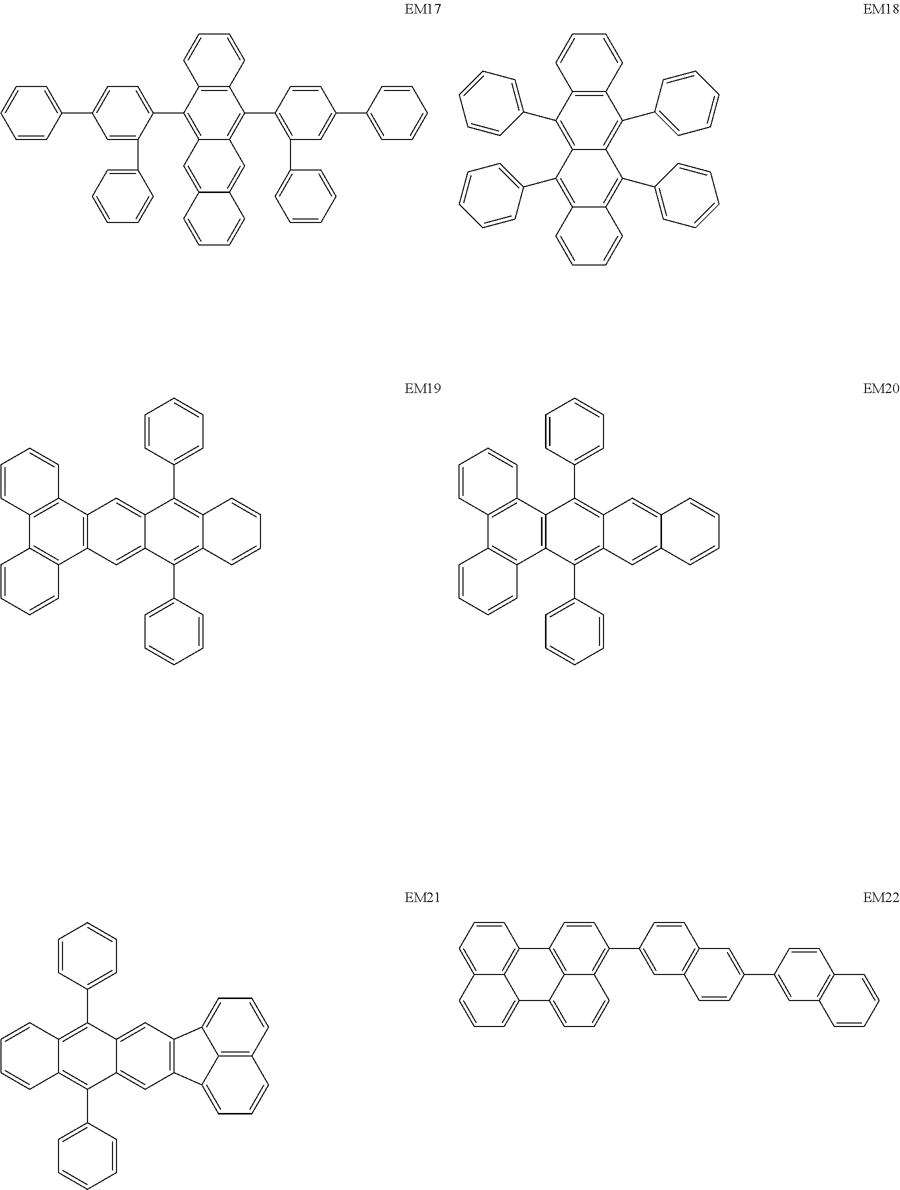

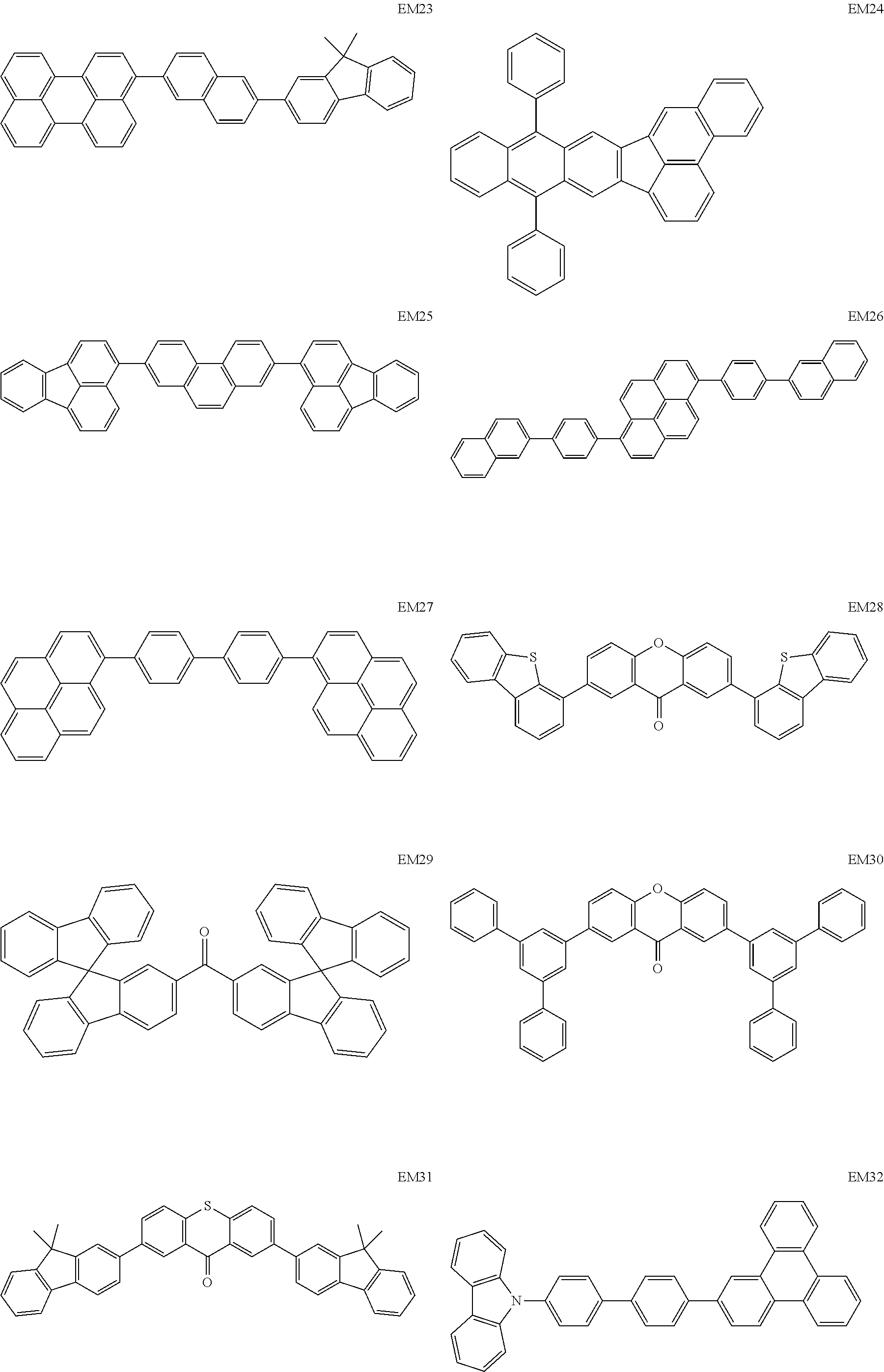

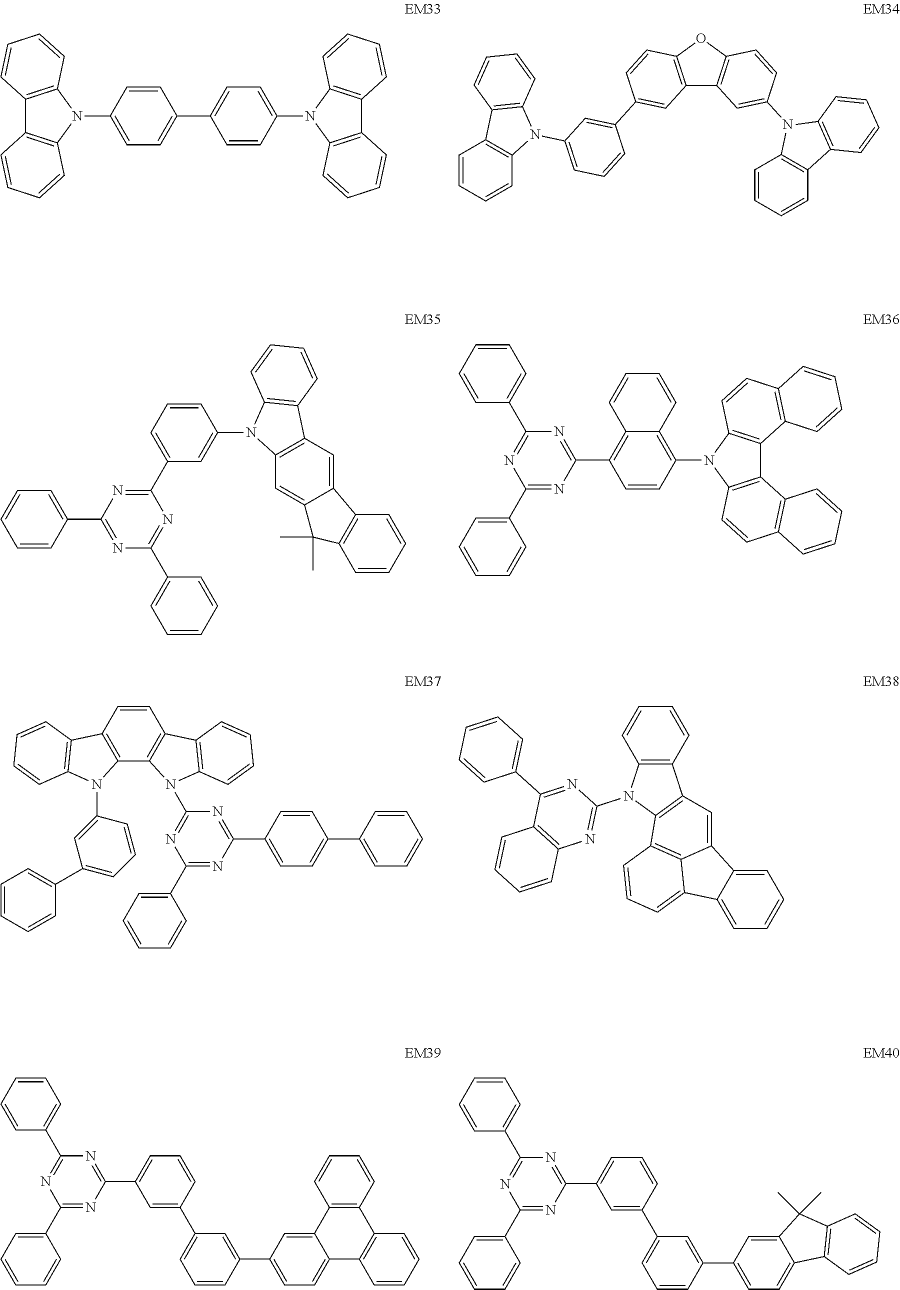

When the host material is a hydrocarbon compound, the light-emitting material easily traps an electron or hole and is effective in improving efficiency. A hydrocarbon compound is a compound composed only of carbon and hydrogen. Exemplary compounds of a hydrocarbon compound are EM1 to EM12 and EM16 to EM27.

An electron-transport material can be selected from materials that can transport electrons injected from a negative electrode to the light-emitting layer and is selected in consideration of the balance with the hole mobility of the hole-transport material and the like. Examples of materials with electron-transport ability include, but are not limited to, oxadiazole derivatives, oxazole derivatives, pyrazine derivatives, triazole derivatives, triazine derivatives, quinoline derivatives, quinoxaline derivatives, phenanthroline derivatives, organoaluminum complexes, and fused-ring compounds (for example, fluorene derivatives, naphthalene derivatives, chrysene derivatives, and anthracene derivatives). Furthermore, the electron-transport material is also suitable for a hole-blocking layer.

Specific examples of compounds that can be used as electron-transport materials are described below. As a matter of course, the present disclosure is not limited to these compounds.

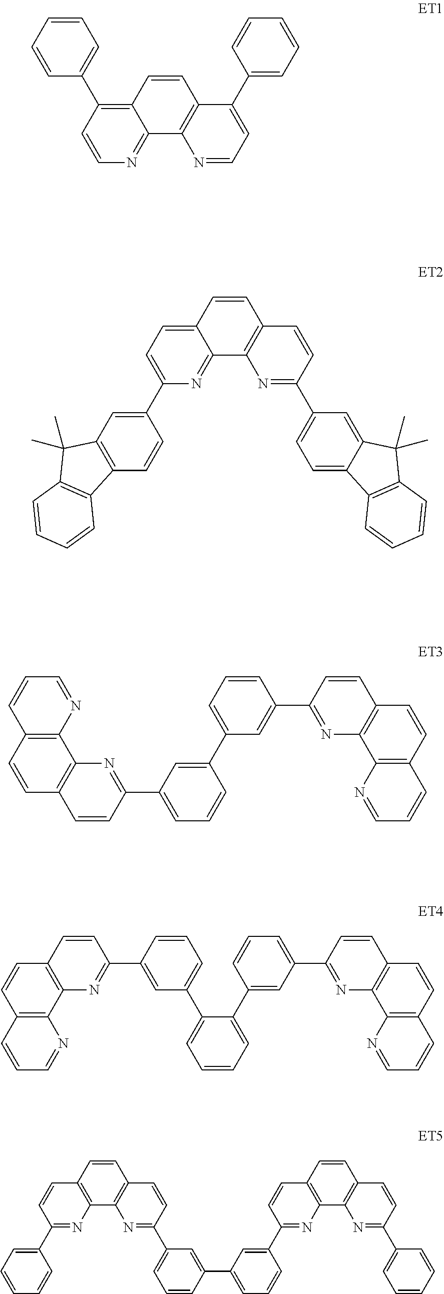

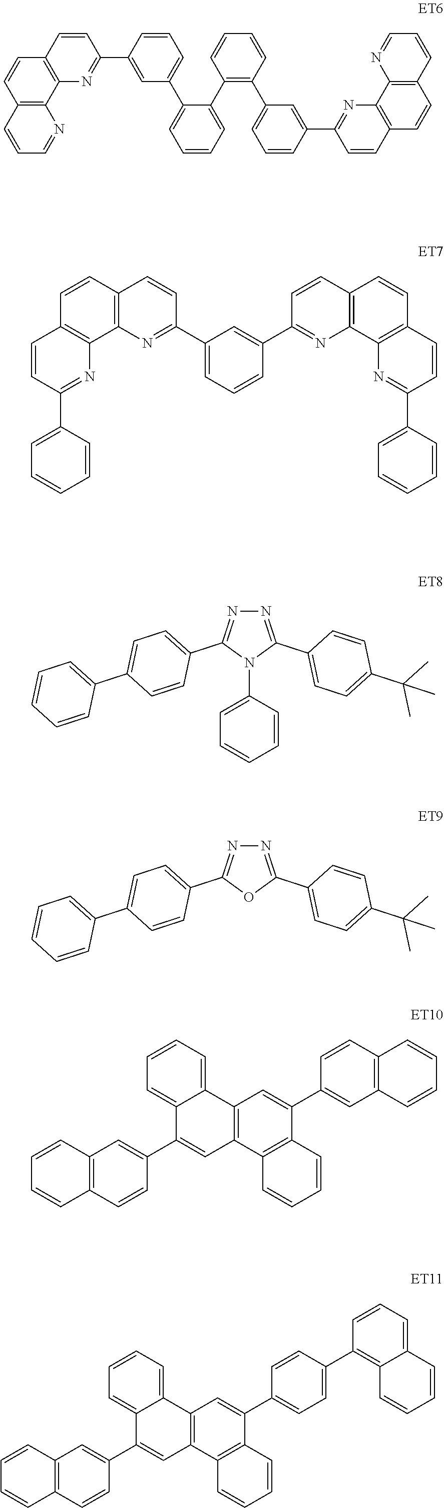

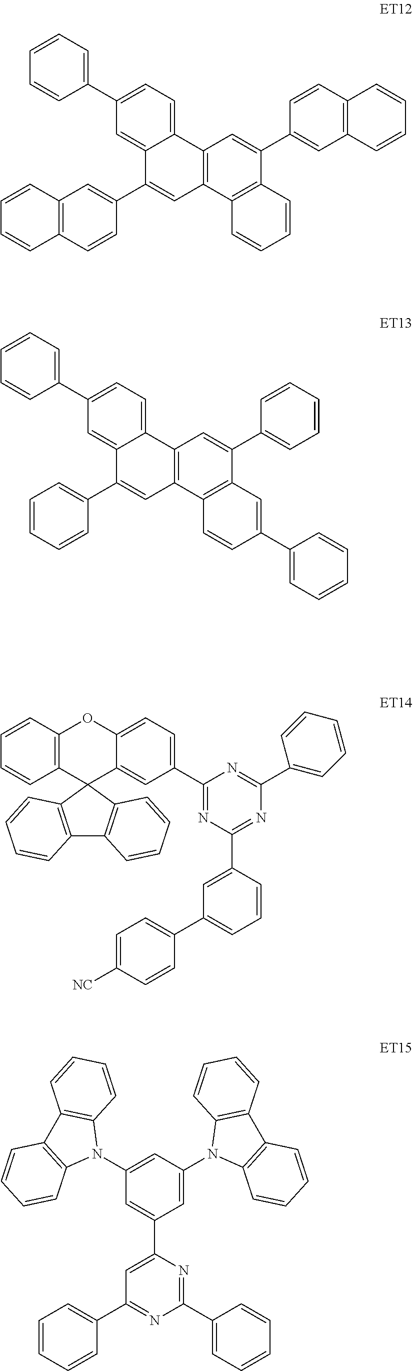

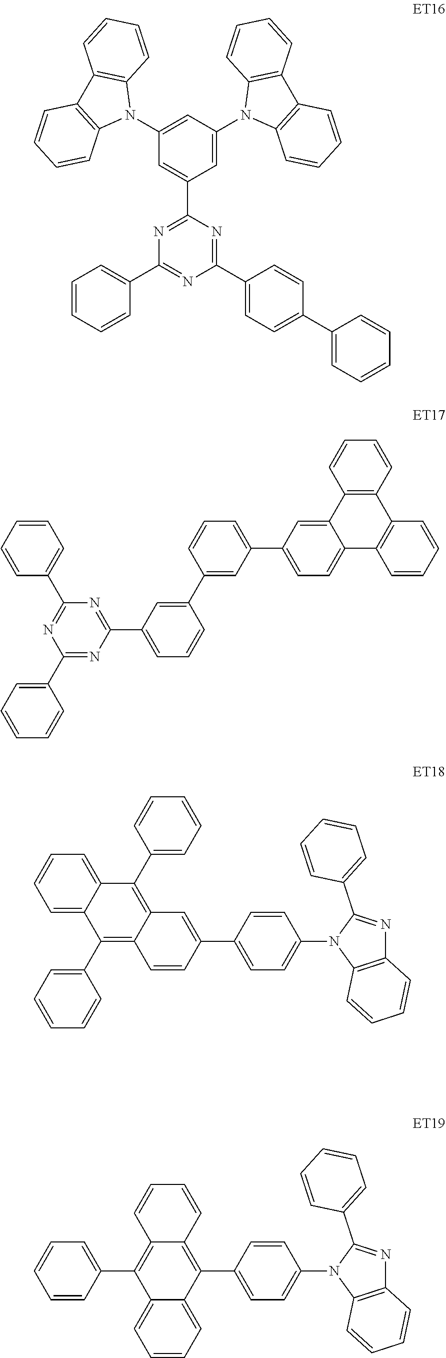 [SMILES: c1ccc(-c2ccc(-c3nc(-c4ccccc4)nc(-c4cc(-n5c6ccccc6c6ccccc65)cc(-n5c6ccccc6c6ccccc65)c4)n3)cc2)cc1 ; c1ccc(-c2nc(-c3ccccc3)nc(-c3cccc(-c4cccc(-c5ccc6c7ccccc7c7ccccc7c6c5)c4)c3)n2)cc1 ; c1ccc(-c2c3ccccc3c(-c3ccccc3)c3cc(-c4ccc(-n5c(-c6ccccc6)nc6ccccc65)cc4)ccc23)cc1 ; c1ccc(-c2c3ccccc3c(-c3ccc(-n4c(-c5ccccc5)nc5ccccc54)cc3)c3ccccc23)cc1]

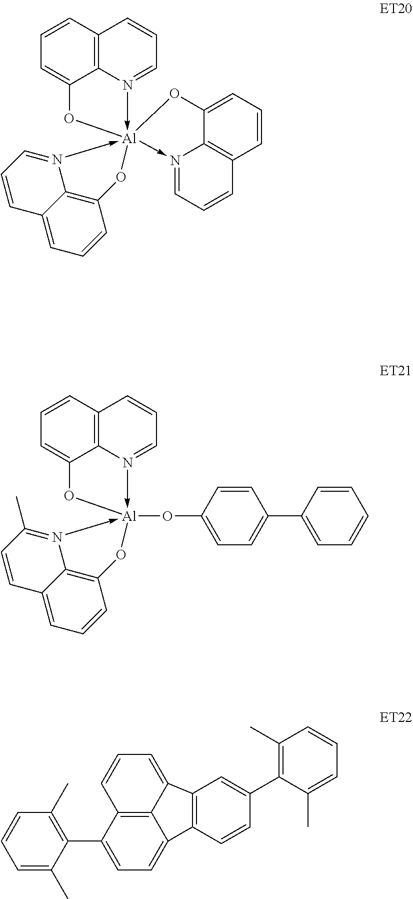

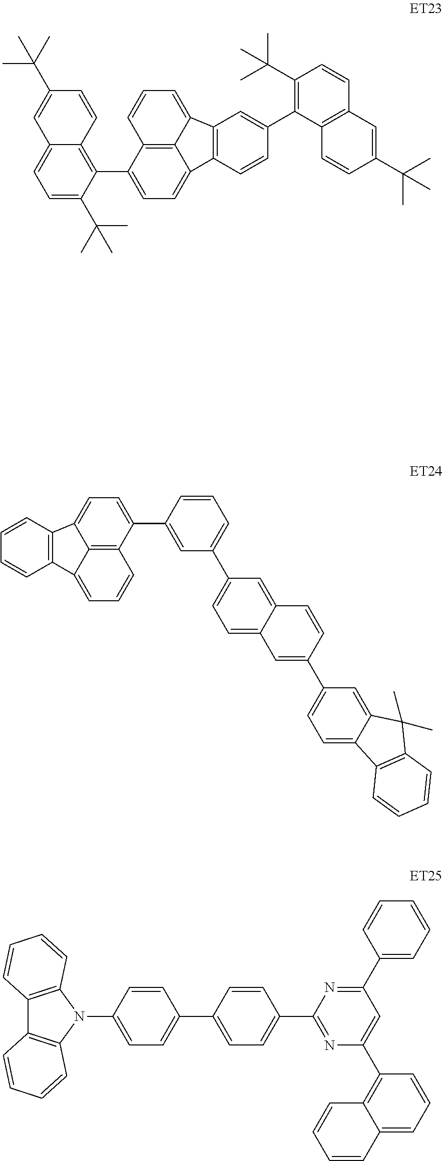

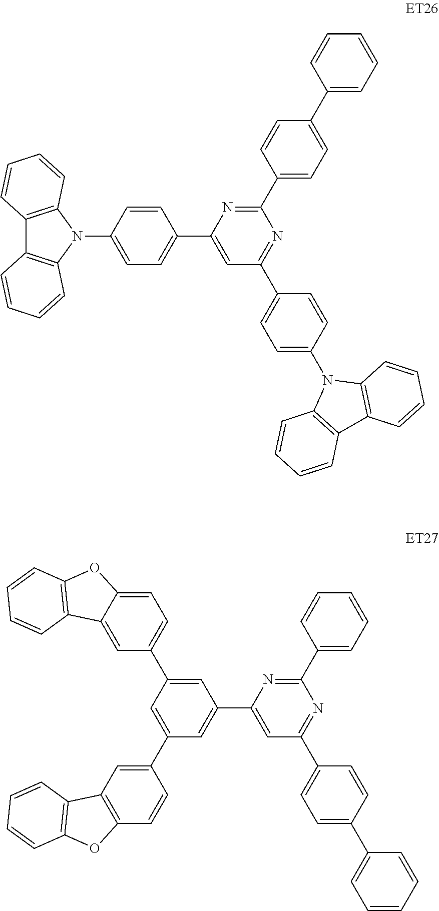 [SMILES: c1ccc(-c2ccc(-c3nc(-c4ccc(-n5c6ccccc6c6ccccc65)cc4)cc(-c4ccc(-n5c6ccccc6c6ccccc65)cc4)n3)cc2)cc1 ; c1ccc(-c2ccc(-c3cc(-c4cc(-c5ccc6oc7ccccc7c6c5)cc(-c5ccc6oc7ccccc7c6c5)c4)nc(-c4ccccc4)n3)cc2)cc1]

The electron-injection material can be selected from materials that can easily inject electrons from the negative electrode and is selected in consideration of the balance with the hole injection properties and the like. Organic compounds include n-type dopants and reducing dopants. Examples include compounds containing an alkali metal, such as lithium fluoride, lithium complexes, such as lithium quinolinol, benzoimidazolidene derivatives, imidazolidene derivatives, fulvalene derivatives, and acridine derivatives.

An organic light-emitting element includes a positive electrode, an organic compound layer, and a negative electrode on a substrate. A protective layer, a color filter, or the like may be provided on the negative electrode. When a color filter is provided, a planarization layer may be provided between the color filter and a protective layer. The planarization layer may be composed of an acrylic resin or the like.

### Structure of Organic Light-Emitting Element

An organic light-emitting element includes an insulating layer, a first electrode, an organic compound layer, and a second electrode on a substrate. A protective layer, a color filter, a microlens, or the like may be provided on the negative electrode. When a color filter is provided, a planarization layer may be provided between the color filter and a protective layer. The planarization layer may be composed of an acrylic resin or the like. The same applies to a planarization layer provided between a color filter and a microlens.

### Substrate

The substrate may be formed of quartz, glass, silicon wafer, resin, metal, or the like. The substrate may have a switching element, such as a transistor, and a wire, on which an insulating layer may be provided. The insulating layer may be composed of any material, provided that the insulating layer can have a contact hole for wiring between the insulating layer and the first electrode and is insulated from unconnected wires. For example, the insulating layer may be formed of a resin, such as polyimide, silicon oxide, or silicon nitride.

### Electrodes

A pair of electrodes can be used as the electrodes. The pair of electrodes may be a positive electrode and a negative electrode. When an electric field is applied in a direction in which the organic light-emitting element emits light, an electrode with a high electric potential is a positive electrode, and the other electrode is a negative electrode. In other words, the electrode that supplies holes to the light-emitting layer is a positive electrode, and the electrode that supplies electrons is a negative electrode.

A constituent material of the positive electrode can have as large a work function as possible. Examples of the constituent material include, but are not limited to, metal elements, such as gold, platinum, silver, copper, nickel, palladium, cobalt, selenium, vanadium, and tungsten, mixtures thereof, alloys thereof, and metal oxides, such as tin oxide, zinc oxide, indium oxide, indium tin oxide (ITO), and indium zinc oxide. Electrically conductive polymers, such as polyaniline, polypyrrole, and polythiophene, may also be used.

These electrode materials may be used alone or in combination. The positive electrode may be composed of a single layer or a plurality of layers.

When used as a reflective electrode, for example, chromium, aluminum, silver, titanium, tungsten, molybdenum, an alloy thereof, or a laminate thereof can be used. These materials can also function as a reflective film that does not have a role as an electrode. When used as a transparent electrode, an oxide transparent conductive layer, such as indium tin oxide (ITO) or indium zinc oxide, can be used. However, the present disclosure is not limited thereto. The electrodes may be formed by photolithography.

A constituent material of the negative electrode can be a material with a small work function. For example, an alkali metal, such as lithium, an alkaline-earth metal, such as calcium, a metal element, such as aluminum, titanium, manganese, silver, lead, or chromium, or a mixture thereof may be used. An alloy of these metal elements may also be used. For example, magnesium-silver, aluminum-lithium, aluminum-magnesium, silver-copper, or zinc-silver may be used. A metal oxide, such as indium tin oxide (ITO), may also be used. These electrode materials may be used alone or in combination. The negative electrode may be composed of a single layer or a plurality of layers. Among them, silver can be used, and a silver alloy can be used to reduce the aggregation of silver. As long as the aggregation of silver can be reduced, the alloy may have any ratio. For example, the ratio of silver to another metal may be 1:1, 3:1, or the like.

The negative electrode may be an oxide conductive layer, such as ITO, for a top emission device or may be a reflective electrode, such as aluminum (Al), for a bottom emission device. The negative electrode may be formed by any method. A direct-current or alternating-current sputtering method can achieve good film coverage and easily decrease resistance.

### Organic Compound Layer

The organic compound layer may be formed of a single layer or a plurality of layers. Depending on their functions, a plurality of layers may be referred to as a hole-injection layer, a hole-transport layer, an electron-blocking layer, a light-emitting layer, a hole-blocking layer, an electron-transport layer, or an electron-injection layer. The organic compound layer is mainly composed of an organic compound and may contain an inorganic atom or an inorganic compound. For example, the compound layer may contain copper, lithium, magnesium, aluminum, iridium, platinum, molybdenum, zinc, or the like.

The organic compound layer may be located between the first electrode and the second electrode and may be in contact with the first electrode and the second electrode.

### Protective Layer

A protective layer may be provided on the negative electrode. For example, a glass sheet with a moisture absorbent may be attached to the negative electrode to prevent water or the like from entering the organic compound layer and reduce the occurrence of display defects. In another embodiment, a passivation film, such as silicon nitride, may be provided on the negative electrode to prevent water or the like from entering the organic compound layer. For example, after the negative electrode is formed, the negative electrode is transferred to another chamber without breaking the vacuum, and a silicon nitride film with a thickness of 2 μm may be formed as a protective layer by a CVD method. The protective layer may be formed by the CVD method followed by an atomic layer deposition (ALD) method. A film formed by the ALD method may be formed of any material such as silicon nitride, silicon oxide, or aluminum oxide. Silicon nitride may be further deposited by the CVD method on the film formed by the ALD method. The film formed by the ALD method may have a smaller thickness than the film formed by the CVD method. More specifically, the thickness of the film formed by the ALD method may be 50% or less or even 10% or less of the thickness of the film formed by the CVD method.

### Color Filter

A color filter may be provided on the protective layer. For example, a color filter that matches the size of the organic light-emitting element may be provided on another substrate and may be bonded to the substrate on which the organic light-emitting element is provided, or a color filter may be patterned on the protective layer by photolithography. The color filter may be composed of a polymer.

### Planarization Layer

A planarization layer may be provided between the color filter and the protective layer. The planarization layer is provided to reduce the roughness of the underlayer. The planarization layer is sometimes referred to as a material resin layer with any purpose. The planarization layer may be composed of an organic compound and can be composed of a high-molecular-weight compound, though it may be composed of a low-molecular-weight compound.

The planarization layer may be provided above and below the color filter, and the constituent materials thereof may be the same or different. Specific examples include polyvinylcarbazole resins, polycarbonate resins, polyester resins, ABS resins, acrylic resins, polyimide resins, phenolic resins, epoxy resins, silicone resins, and urea resins.

### Microlens

The organic light-emitting element may include an optical member, such as a microlens, on the light output side. The microlens may be composed of an acrylic resin, an epoxy resin, or the like. The microlens may be used to increase the amount of light extracted from the organic light-emitting element and control the direction of the extracted light. The microlens may have a hemispherical shape. For a hemispherical microlens, the vertex of the microlens is a contact point between the hemisphere and a tangent line parallel to the insulating layer among the tangent lines in contact with the hemisphere. The vertex of the microlens in a cross-sectional view can be determined in the same manner. More specifically, the vertex of the microlens in a cross-sectional view is a contact point between the semicircle of the microlens and a tangent line parallel to the insulating layer among the tangent lines in contact with the semicircle.

The midpoint of the microlens can also be defined. In a cross section of the microlens, a midpoint of a line segment from one end point to the other end point of the arc can be referred to as a midpoint of the microlens. A cross section in which the vertex and the midpoint are determined may be perpendicular to the insulating layer.

### Opposite Substrate

An opposite substrate may be provided on the planarization layer. The opposite substrate is so called because it faces the substrate. The opposite substrate may be composed of the same material as the substrate. When the substrate is a first substrate, the opposite substrate may be a second substrate.

### Organic Layer

An organic compound layer (a hole-injection layer, a hole-transport layer, layer, an electron-injection layer, etc.) constituting an organic light-emitting element according to an embodiment of the present disclosure is formed by the following method.

An organic compound layer constituting an organic light-emitting element according to an embodiment of the present disclosure can be formed by a dry process, such as a vacuum evaporation method, an ionized deposition method, sputtering, or plasma. Instead of the dry process, a wet process may also be employed in which a layer is formed by a known coating method (for example, spin coating, dipping, a casting method, an LB method, an ink jet method, etc.) using an appropriate solvent.

A layer formed by a vacuum evaporation method, a solution coating method, or the like undergoes little crystallization or the like and has high temporal stability. When a film is formed by a coating method, the film may also be formed in combination with an appropriate binder resin.

Examples of the binder resin include, but are not limited to, polyvinylcarbazole resins, polycarbonate resins, polyester resins, ABS resins, acrylic resins, polyimide resins, phenolic resins, epoxy resins, silicone resins, and urea resins.

These binder resins may be used alone as a homopolymer or a copolymer or may be used in combination. If necessary, an additive agent, such as a known plasticizer, antioxidant, and/or ultraviolet absorber, may also be used.

### Pixel Circuit

An organic light-emitting apparatus may include a pixel circuit coupled to the organic light-emitting element. The pixel circuit may be of an active matrix type, which independently controls the light emission of a first light-emitting element and a second light-emitting element. The active-matrix circuit may be of voltage programming or current programming. The drive circuit has a pixel circuit for each pixel. The pixel circuit may include a light-emitting element, a transistor for controlling the luminance of the light-emitting element, a transistor for controlling light emission timing, a capacitor for holding the gate voltage of the transistor for controlling the luminance, and a transistor for GND connection without through the light-emitting element.

The driving current may depend on the size of the light-emitting region. More specifically, when the first light-emitting element and the second light-emitting element are made to emit light of the same luminance, the first light-emitting element may have a smaller current value than the second light-emitting element. This is because the required current may be small due to a small light-emitting region.

### Pixel

An organic light-emitting apparatus has a plurality of pixels. Each pixel has subpixels that emit light of different colors. For example, the subpixels may have RGB emission colors.

In each pixel, a region also referred to as a pixel aperture emits light. This region is the same as the first region. The pixel aperture may be 15 μm or less or 5 μm or more. More specifically, the pixel aperture may be 11 μm, 9.5 μm, 7.4 μm, 6.4 μm, or the like.

The distance between the subpixels may be 10 μm or less, more specifically, 8 μm, 7.4 μm, or 6.4 μm.

The pixels may be arranged in a known form in a plan view. Examples include stripe arrangement, delta arrangement, PenTile arrangement, and Bayer arrangement. Each subpixel may have any known shape in a plan view. Examples include quadrangles, such as a rectangle and a rhombus, and a hexagon. As a matter of course, a figure that is not strictly rectangular but is close to rectangular is also included in the rectangle. The shape of each subpixel and the pixel array can be used in combination.

### Applications of Organic Light-Emitting Element according to Embodiment of Present Disclosure

An organic light-emitting element according to an embodiment of the present disclosure can be used as a constituent of a display apparatus or a lighting apparatus. Other applications include an exposure light source of an electrophotographic image-forming apparatus, a backlight of a liquid crystal display, and a light-emitting apparatus with a color filter in a white light source.

The display apparatus may include an image input unit for inputting image information from an area CCD, a linear CCD, a memory card, or the like, may include an apparatus for displaying an input image on a display unit.

A display unit of an imaging apparatus or an ink jet printer may have a touch panel function. A driving system of the touch panel function may be, but is not limited to, an infrared radiation system, an electrostatic capacitance system, a resistive film system, or an electromagnetic induction system. The display apparatus may be used as a display of a multifunction printer.

Next, the display apparatus according to the present embodiment is described with reference to the accompanying drawings.

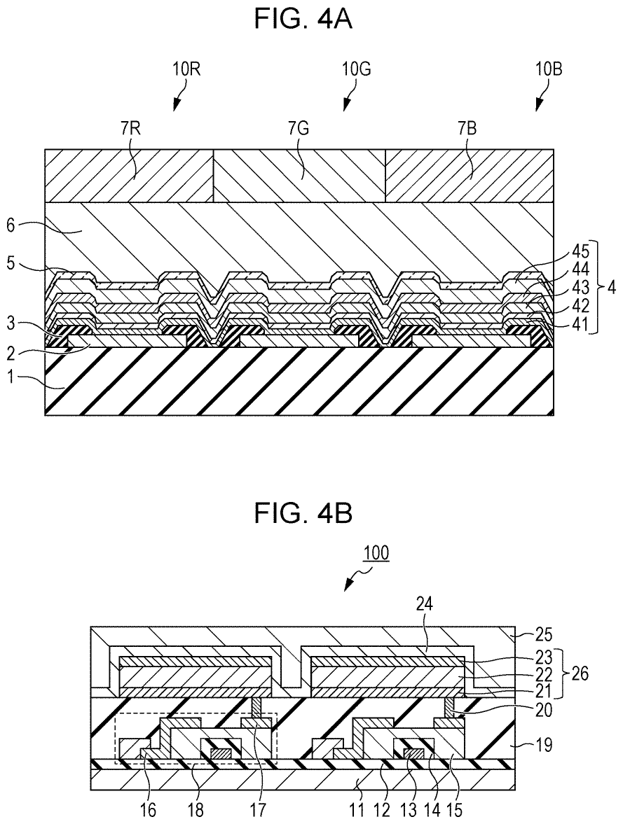

FIGS. 4A and 4B are schematic cross-sectional views of a display apparatus that includes an organic light-emitting element and a transistor coupled to the organic light-emitting element. The transistor is an example of an active element. The transistor may be a thin-film transistor (TFT).

FIG. 4A illustrates a pixel serving as a constituent of the display apparatus according to the present embodiment. The pixel has subpixels 10. The subpixels are 10R, 10G, and 10B with different emission colors. The emission colors may be distinguished by the wavelength emitted from the light-emitting layer, or light emitted from each subpixel may be selectively transmitted or color-converted with a color filter or the like. Each subpixel has, on an interlayer insulating layer 1, a reflective electrode 2 as a first electrode, an insulating layer 3 covering the ends of the reflective electrode 2, organic compound layers 4 covering the first electrode and the insulating layer, a second electrode 5, a protective layer 6, and a color filter 7.

A transistor and/or a capacitor element may be provided under or inside the interlayer insulating layer 1. The transistor may be electrically connected to the first electrode via a contact hole (not shown) or the like.

The insulating layer 3 is also referred to as a bank or a pixel separation film. The insulating layer 3 covers the ends of the first electrode and surrounds the first electrode. A portion of the first electrode not covered with the insulating layer is in contact with the organic compound layers 4 and serves as a light-emitting region.

The organic compound layers 4 include a hole-injection layer 41, a hole-transport layer 2, a first light-emitting layer 43, a second light-emitting layer 44, and an electron-transport layer 45.

The second electrode 5 may be a transparent electrode, a reflective electrode, or a semitransparent electrode.

The protective layer 6 reduces the penetration of moisture into the organic compound layers. The protective layer is illustrated as a single layer but may be a plurality of layers. The protective layer may include an inorganic compound layer and an organic compound layer.

The color filter 7 is divided into 7R, 7G, and 7B according to the color. The color filter may be formed on a planarizing film (not shown). Furthermore, a resin protective layer (not shown) may be provided on the color filter. The color filter may be formed on the protective layer 6. Alternatively, the color filter may be bonded after being provided on an opposite substrate, such as a glass substrate.

A display apparatus 100 in FIG. 4B includes an organic light-emitting element 26 and a TFT 18 as an example of a transistor. The display apparatus 100 includes a substrate 11 made of glass, silicon, or the like and an insulating layer 12 on the substrate 11. The display apparatus 100 includes, on the insulating layer, an active element 18, such as a TFT, and a gate electrode 13, a gate-insulating film 14, and a semiconductor layer 15 of the active element. The TFT 18 is also composed of a drain electrode 16 and a source electrode 17. The TFT 18 is covered with an insulating film 19. A positive electrode 21 of the organic light-emitting element 26 is coupled to the source electrode 17 through a contact hole 20 formed in the insulating film.

Electrical connection between electrodes of the organic light-emitting element 26 (the positive electrode and a negative electrode) and the electrodes of the TFT (the source electrode and the drain electrode) is not limited to that illustrated in FIG. 4B. More specifically, it is only necessary to electrically connect one of the positive electrode and the negative electrode to one of the source electrode and the drain electrode of the TFT. TFT refers to a thin-film transistor.

Although an organic compound layer 22 is a single layer in the display apparatus 100 illustrated in FIG. 4B, the organic compound layer 22 may be composed of a plurality of layers. A first protective layer 24 and a second protective layer 25 for reducing degradation of the organic light-emitting element are provided on a negative electrode 23.

The transistor used as a switching element in the display apparatus 100 illustrated in FIG. 4B may be replaced with another switching element.

The transistor used in the display apparatus 100 in FIG. 4B is not limited to a transistor including a single crystal silicon wafer and may also be a thin-film transistor including an active layer on an insulating surface of a substrate. The active layer may be single-crystal silicon, non-single-crystal silicon, such as amorphous silicon or microcrystalline silicon, or a non-single-crystal oxide semiconductor, such as indium zinc oxide or indium gallium zinc oxide. The thin-film transistor is also referred to as a TFT element.

The transistor in the display apparatus 100 of FIG. 4B may be formed within a substrate, such as a Si substrate. The phrase “formed within a substrate” means that the substrate, such as a Si substrate, itself is processed to form the transistor. Thus, the transistor within the substrate can be considered that the substrate and the transistor are integrally formed.

In the organic light-emitting element according to the present embodiment, the luminance is controlled with the TFT, which is an example of a switching element. The organic light-emitting element can be provided on a plurality of planes to display an image at each luminance. The switching element according to the present embodiment is not limited to the TFT and may be a transistor formed of low-temperature polysilicon or an active-matrix driver formed on a substrate, such as a S₁ substrate. “On a substrate” may also be referred to as “within a substrate”. Whether a transistor is provided within a substrate or a TFT is used depends on the size of a display unit. For example, for a display unit with approximately 0.5 inches, an organic light-emitting element can be provided on a S₁ substrate.

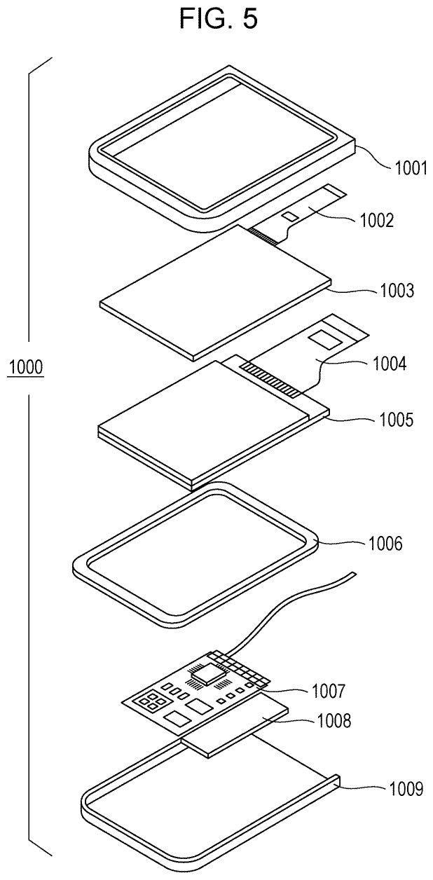

FIG. 5 is a schematic view of an example of the display apparatus according to the present embodiment. A display apparatus 1000 may include a touch panel 1003, a display panel 1005, a frame 1006, a circuit substrate 1007, and a battery 1008 between an upper cover 1001 and a lower cover 1009. The touch panel 1003 and the display panel 1005 are coupled to flexible print circuits FPC 1002 and 1004, respectively. Transistors are printed on the circuit substrate 1007. The battery 1008 may not be provided when the display apparatus is not a mobile device, or may be provided at another position even when the display apparatus is a mobile device.

The display apparatus according to the present embodiment may include color filters of red, green, and blue colors. The color filters may be arranged such that the red, green, and blue colors are arranged in a delta arrangement.

The display apparatus according to the present embodiment may be used for a display unit of a mobile terminal. Such a display apparatus may have both a display function and an operation function. Examples of the mobile terminal include mobile phones, such as smartphones, tablets, and head-mounted displays.

The display apparatus according to the present embodiment may be used in a display unit of an imaging apparatus that includes an optical unit with a plurality of lenses and an imaging element for receiving light passing through the optical unit. The imaging apparatus may include a display unit for displaying information acquired by the imaging element. The display unit may be a display unit exposed outside from the imaging apparatus or a display unit located in a finder. The imaging apparatus may be a digital camera or a digital video camera.

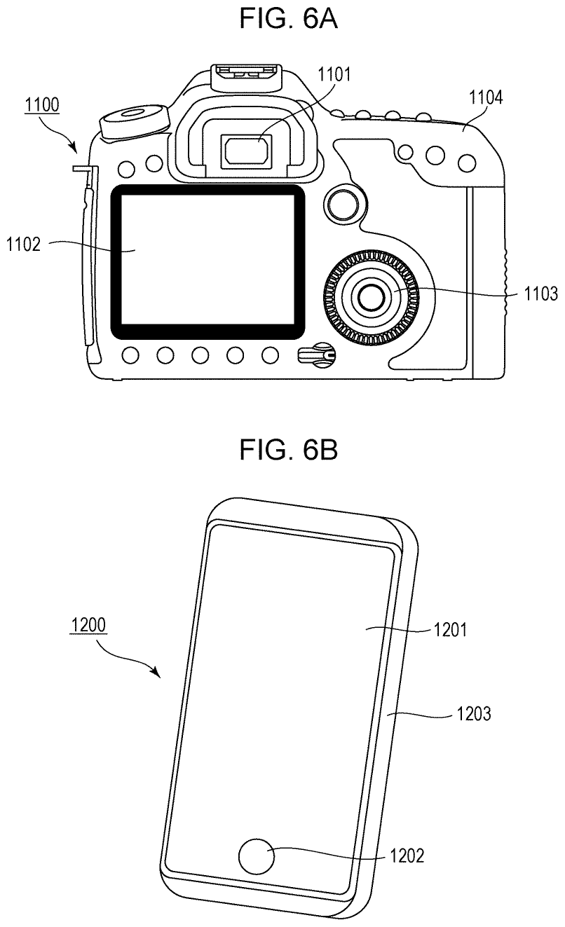

FIG. 6A is a schematic view of an example of an imaging apparatus according to the present embodiment. An imaging apparatus 1100 may include a viewfinder 1101, a rear display 1102, an operating unit 1103, and a housing unit 1104. The viewfinder 1101 may include the display apparatus according to the present embodiment. In such a case, the display apparatus may display environmental information, imaging instructions, and the like as well as an image to be captured. The environmental information may include the intensity and direction of external light, the travel speed of the photographic subject, and the possibility that the photographic subject is shielded by a shield, and the like.

Because the appropriate timing for imaging is a short time, it is better to display information as soon as possible. Thus, a display apparatus including an organic light-emitting element according to the present disclosure can be used. This is because the organic light-emitting element has a high response speed. A display apparatus including the organic light-emitting element can be more suitably used than these apparatuses and liquid crystal displays that require a high display speed.

The imaging apparatus 1100 includes an optical unit (not shown). The optical unit has a plurality of lenses and focuses an image on an imaging element in the housing 1104. The focus of the lenses can be adjusted by adjusting their relative positions. This operation can also be automatically performed. The imaging apparatus may also be referred to as a photoelectric conversion apparatus. The photoelectric conversion apparatus can have, as an imaging method, a method of detecting a difference from a previous image or a method of cutting out a permanently recorded image, instead of taking an image one after another.

FIG. 6B is a schematic view of an example of electronic equipment according to the present embodiment. Electronic equipment 1200 includes a display unit 1201, an operating unit 1202, and a housing 1203. The housing 1203 may include a circuit, a printed circuit board including the circuit, a battery, and a communication unit. The operation unit 1202 may be a button or a touch panel response unit. The operating unit may be a biometric recognition unit that recognizes a fingerprint and releases the lock. Electronic equipment including a communication unit may also be referred to as a communication apparatus. The electronic equipment may have a lens and an imaging element and thereby further have a camera function. An image captured by the camera function is displayed on the display unit. The electronic equipment may be a smartphone, a notebook computer, or the like.

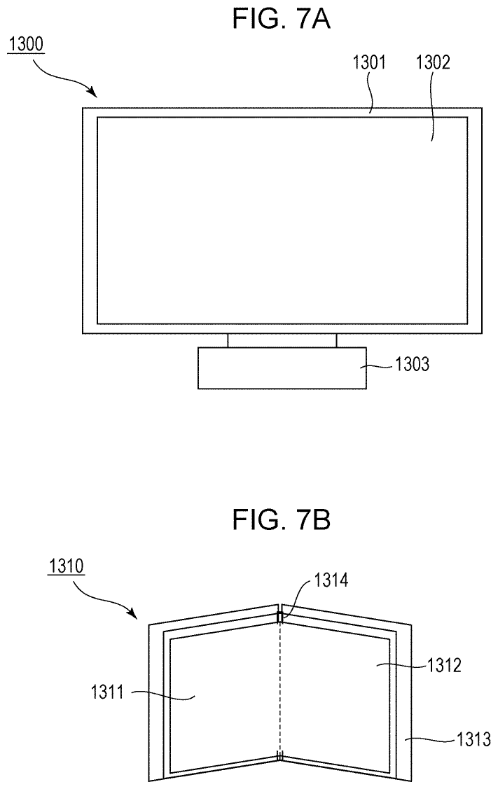

FIGS. 7A and 7B are schematic views of an example of the display apparatus according to the present embodiment. FIG. 7A illustrates a display apparatus, such as a television monitor or a PC monitor. A display apparatus 1300 includes a frame 1301 and a display unit 1302. The light-emitting apparatus according to the present embodiment may be used for the display unit 1302.

The frame 1301 and the display unit 1302 are supported by a base 1303. The base 1303 is not limited to the structure illustrated in FIG. 7A. The lower side of the frame 1301 may also serve as the base.

The frame 1301 and the display unit 1302 may be bent. The radius of curvature may range from 5000 to 6000 mm.

FIG. 7B is a schematic view of another example of the display apparatus according to the present embodiment. A display apparatus 1310 illustrated in FIG. 7B is a so-called foldable display apparatus with a foldable display surface. The display apparatus 1310 includes a first display unit 1311, a second display unit 1312, a housing 1313, and a folding point 1314. The first display unit 1311 and the second display unit 1312 may include the light-emitting apparatus according to the present embodiment. The first display unit 1311 and the second display unit 1312 may be a single display apparatus without a joint. The first display unit 1311 and the second display unit 1312 can be divided by a folding point. The first display unit 1311 and the second display unit 1312 may display different images or one image.

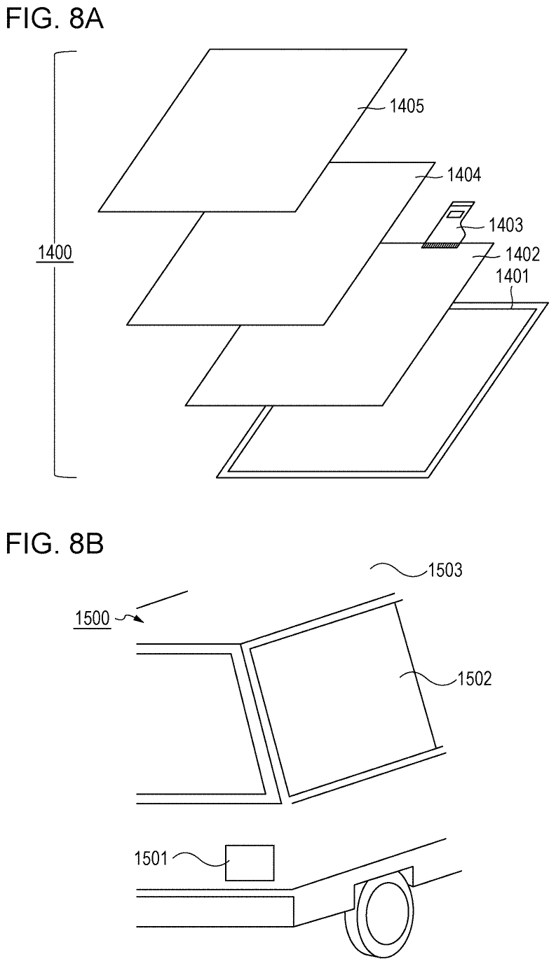

FIG. 8A is a schematic view of an example of a lighting apparatus according to the present embodiment. A lighting apparatus 1400 may include a housing 1401, a light source 1402, a circuit board 1403, an optical film 1404, and a light-diffusing unit 1405. The light source may include the organic light-emitting element according to the present embodiment. The optical filter may be a filter for improving the color rendering properties of the light source. The light-diffusing unit can effectively diffuse light from the light source and widely spread light as in illumination. The optical filter and the light-diffusing unit may be provided on the light output side of the illumination. If necessary, a cover may be provided on the outermost side.

For example, the lighting apparatus is an interior lighting apparatus. The lighting apparatus may emit white light, neutral white light, or light of any color from blue to red. The lighting apparatus may have a light control circuit for controlling such light. The lighting apparatus may include an organic light-emitting element according to the present disclosure and a power supply circuit coupled thereto. The power supply circuit converts an AC voltage to a DC voltage. White has a color temperature of 4200 K, and neutral white has a color temperature of 5000 K. The lighting apparatus may have a color filter.

The lighting apparatus according to the present embodiment may include a heat dissipation unit. The heat dissipation unit releases heat from the apparatus to the outside and may be a metal or liquid silicon with a high specific heat.

FIG. 8B is a schematic view of an automobile as an example of a moving body according to the present embodiment. The automobile has a taillight as an example of a lamp. An automobile 1500 may have a taillight 1501, which comes on when a brake operation or the like is performed.

The taillight 1501 may include the organic light-emitting element according to the present embodiment. The taillight may include a protective member for protecting the organic light-emitting element. The protective member may be formed of any transparent material with moderately high strength and can be formed of polycarbonate or the like. The polycarbonate may be mixed with a furan dicarboxylic acid derivative, an acrylonitrile derivative, or the like.

The automobile 1500 may have a body 1503 and a window 1502 on the body 1503. The window may be a transparent display as long as it is not a window for checking the front and rear of the automobile. The transparent display may include the organic light-emitting element according to the present embodiment. In such a case, constituent materials, such as electrodes, of the organic light-emitting element are transparent materials.

The moving body according to the present embodiment may be a ship, an aircraft, a drone, or the like. The moving body may include a body and a lamp provided on the body. The lamp may emit light to indicate the position of the body. The lamp includes the organic light-emitting element according to the present embodiment.

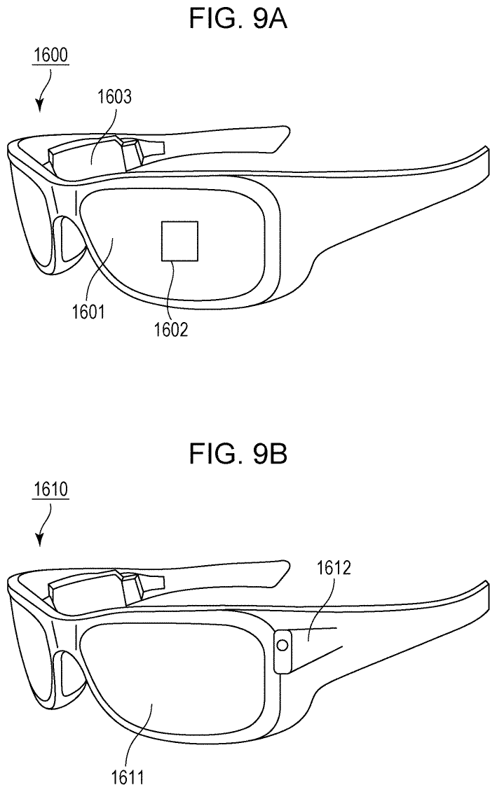

FIGS. 9A and 9B illustrate a display apparatus as an example of a wearable device including an organic light-emitting element according to the present disclosure. The display apparatus can be applied to a system that can be worn as a wearable device, such as smart glasses, a head-mounted display (HMD), or smart contact lenses. An imaging and displaying apparatus used in such an application includes an imaging apparatus that can photoelectrically convert visible light and a display apparatus that can emit visible light.

FIG. 9A illustrates glasses 1600 (smart glasses) according to one application example. An imaging apparatus 1602, such as a complementary metal-oxide semiconductor (CMOS) sensor or a single-photon avalanche photodiode (SPAD), is provided on the front side of a lens 1601 of the glasses 1600. The display apparatus according to one of the embodiments is provided on the back side of the lens 1601.

The glasses 1600 further include a controller 1603. The controller 1603 functions as a power supply for supplying power to the imaging apparatus 1602 and the display apparatus according to one of the embodiments. The controller 1603 controls the operation of the imaging apparatus 1602 and the display apparatus. The lens 1601 has an optical system for focusing light on the imaging apparatus 1602.

FIG. 9B illustrates glasses 1610 (smart glasses) according to one application example. The glasses 1610 have a controller 1612, which includes an imaging apparatus corresponding to the imaging apparatus 1602 and a display apparatus. A lens 1611 includes an optical system for projecting light from the imaging apparatus and the display apparatus of the controller 1612, and an image is projected on the lens 1611. The controller 1612 functions as a power supply for supplying power to the imaging apparatus and the display apparatus and controls the operation of the imaging apparatus and the display apparatus. The controller may include a line-of-sight detection unit for detecting the line of sight of the wearer. Infrared radiation may be used to detect the line of sight. An infrared radiation unit emits infrared light to an eyeball of a user who is gazing at a display image. Reflected infrared light from the eyeball is detected by an imaging unit including a light-receiving element to capture an image of the eyeball. A reduction unit for reducing light from the infrared radiation unit to a display unit in a plane view is provided to reduce degradation in image quality.

The line of sight of the user for the display image is detected from the image of the eyeball obtained by capturing the infrared light. Any known technique can be applied to line-of-sight detection using the image of the eyeball. For example, it is possible to use a line-of-sight detection method based on a Purkinje image obtained by reflection of irradiation light by the cornea.

More specifically, a line-of-sight detection process based on a pupil-corneal reflection method is performed. The line of sight of the user is detected by calculating a line-of-sight vector representing the direction (rotation angle) of an eyeball on the basis of an image of a pupil and a Purkinje image included in a captured image of the eyeball using the pupil-corneal reflection method.

A display apparatus according to an embodiment of the present disclosure may include an imaging apparatus including a light-receiving element and may control a display image on the basis of line-of-sight information of a user from the imaging apparatus.

More specifically, on the basis of the line-of-sight information, the display apparatus determines a first visibility region at which the user gazes and a second visibility region other than the first visibility region. The first visibility region and the second visibility region may be determined by the controller of the display apparatus or may be received from an external controller. In the display region of the display apparatus, the first visibility region may be controlled to have higher display resolution than the second visibility region. In other words, the second visibility region may have lower resolution than the first visibility region.

The display region has a first display region and a second display region different from the first display region, and the priority of the first display region and the second display region depends on the line-of-sight information. The first visibility region and the second visibility region may be determined by the controller of the display apparatus or may be received from an external controller. A region with a higher priority may be controlled to have higher resolution than another region. In other words, a region with a lower priority may have lower resolution.

The first visibility region or a region with a higher priority may be determined by artificial intelligence (AI). The AI may be a model configured to estimate the angle of the line of sight and the distance to a target ahead of the line of sight from an image of an eyeball using the image of the eyeball and the direction in which the eyeball actually viewed in the image as teaching data. The AI program may be stored in the display apparatus, the imaging apparatus, or an external device. The AI program stored in an external device is transmitted to the display apparatus via communication.

For display control based on visual recognition detection, the present disclosure can be applied to smart glasses further having an imaging apparatus for imaging the outside. Smart glasses can display captured external information in real time.

As described above, the apparatus including the organic light-emitting element according to the present embodiment can be used to stably display a high-quality image for extended periods.

### EXAMPLES

The present disclosure is described below with exemplary embodiments. However, the present disclosure is not limited these exemplary embodiments.

The following exemplary compounds were used in the exemplary embodiments. Although Exemplary Compounds 1 to 7 were used as the second organic compounds, the present disclosure is not limited to these exemplary compounds. Exemplary Compounds 8 to 12 were also used in the present specification.

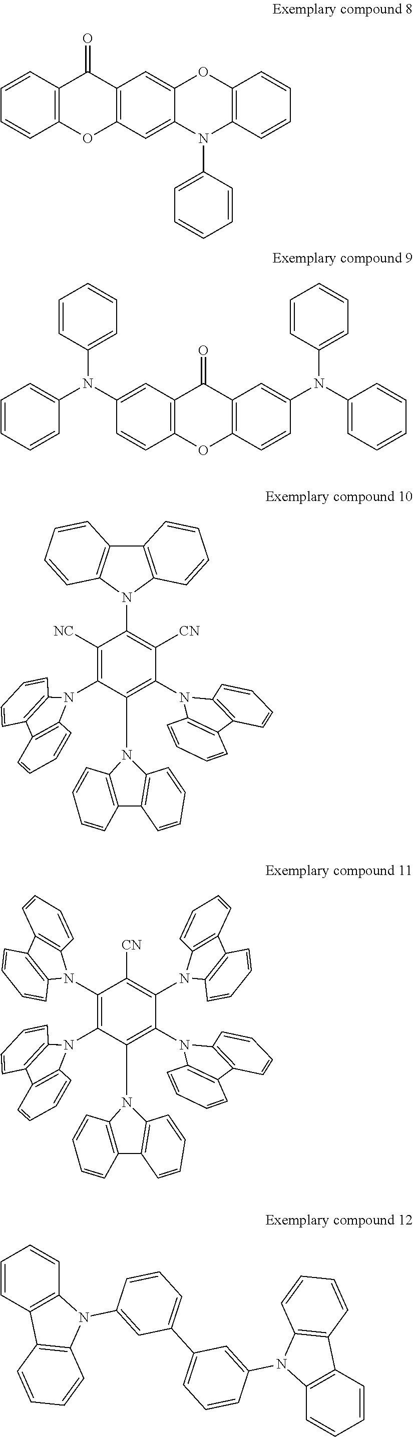 [SMILES: O=c1c2ccccc2oc2cc3c(cc12)Oc1ccccc1N3c1ccccc1 ; O=c1c2cc(N(c3ccccc3)c3ccccc3)ccc2oc2ccc(N(c3ccccc3)c3ccccc3)cc12 ; N#Cc1c(-n2c3ccccc3c3ccccc32)c(C#N)c(-n2c3ccccc3c3ccccc32)c(-n2c3ccccc3c3ccccc32)c1-n1c2ccccc2c2ccccc21 ; N#Cc1c(-n2c3ccccc3c3ccccc32)c(-n2c3ccccc3c3ccccc32)c(-n2c3ccccc3c3ccccc32)c(-n2c3ccccc3c3ccccc32)c1-n1c2ccccc2c2ccccc21 ; c1cc(-c2cccc(-n3c4ccccc4c4ccccc43)c2)cc(-n2c3ccccc3c3ccccc32)c1]

### Synthesis Example 1

Exemplary Compound 2 was synthesized in accordance with the following scheme.

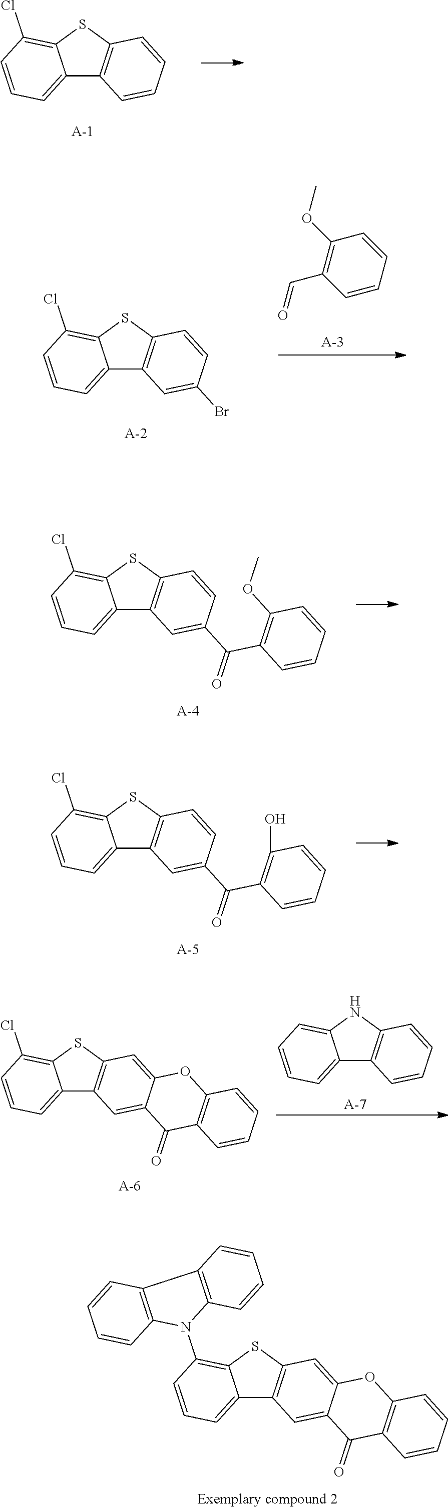

(1) Synthesis of Compound A-2

A 500-ml recovery flask was charged with the following reagents and solvent.

Compound A-1: 5.0 g (22.9 mmol)

Br2: 11.0 g (68.6 mmol)

Chloroform: 200 ml

The reaction solution was then cooled to 0° C. in a nitrogen stream, and 11.0 g of bromine was added dropwise to the reaction solution. After the dropwise addition, the reaction solution was stirred at room temperature for 8 hours. The reaction solution was poured into ice water. An organic phase was extracted with toluene and was concentrated to dryness to prepare a solid.

The solid was purified by silica gel column chromatography (toluene:heptane) to yield 3.7 g of A-2 (yield: 55%).

(2) Synthesis of Compound A-4

A 300-ml Schlenk flask was charged with the following reagents and solvent.

Compound A-2: 3.5 g (11.8 mmol)

Compound A-3: 3.2 g (23.5 mmol)

DMF: 175 ml

The reaction solution was then heated with stirring at 120° C. for 12 hours in a nitrogen stream. After completion of the reaction, 100 ml of diluted hydrochloric acid was added to the reaction solution, and the reaction solution was filtered. 2.9 g of A-4 was obtained (yield: 70%).

(3) Synthesis of Compound A-5

A 500-ml recovery flask was charged with the following reagent and solvent.

Compound A-4: 4.0 g (11.3 mmol)

Pyridine hydrochloride: 200 g

The reaction solution was then heated with stirring at 230° C. for 24 hours in a nitrogen stream. After completion of the reaction, 100 ml of hot water was added to the reaction solution, and the reaction solution was filtered. The resulting solid was purified by silica gel column chromatography (toluene:ethyl acetate mixture) to yield 3.1 g of A-5 (yield: 80%).

(4) Synthesis of Compound A-6

A 200-ml recovery flask was charged with the following reagents and solvents.

Compound A-5: 2.5 g (7.4 mmol)

Pd(OAc)2: 0.2 g (0.7 mmol)

3-nitropyridine: 90 mg

Hexafluorobenzene: 7 ml

DMI: 7 ml

tert-butyl perbenzoate: 2.9 g

The reaction solution was then heated under reflux with stirring at 90° C. for 7 hours in a nitrogen stream. After completion of the reaction, the reaction solution was filtered through Celite and was concentrated and dried to a solid. The solid was purified by silica gel column chromatography (toluene) to yield 1.6 g of A-6 (yield: 65%).

(5) Synthesis of Exemplary Compound 2

A 500-ml recovery flask was charged with the following reagents and solvent.

Compound A-6: 1.0 g (3.0 mmol)

Compound A-7: 0.6 g (3.6 mmol)

Sodium t-butoxide: 0.47 g (4.90 mmol)

Pd(dba)2: 170 mg

XPhos: 420 mg

o-xylene: 50 ml

The reaction solution was then heated with stirring at 140° C. for 5 hours in a nitrogen stream. After completion of the reaction, the reaction solution was filtered through Celite and was concentrated to dryness. The resulting solid was purified by silica gel column chromatography (toluene) to yield 0.87 g of Exemplary Compound 2 as a white solid (yield: 63%).

Exemplary Compound 2 was subjected to mass spectrometry with MALDI-TOF-MS (Autoflex LRF manufactured by Bruker).

### [MALDI-TOF-MS]

Actual value: m/z=467.21 Calculated value: C₃₁H₁₇NO₂S=467.54

A synthetic example of Exemplary Compound 5 is described below.

### Synthesis Example 2

Exemplary Compound 5 was synthesized in accordance with the following scheme.

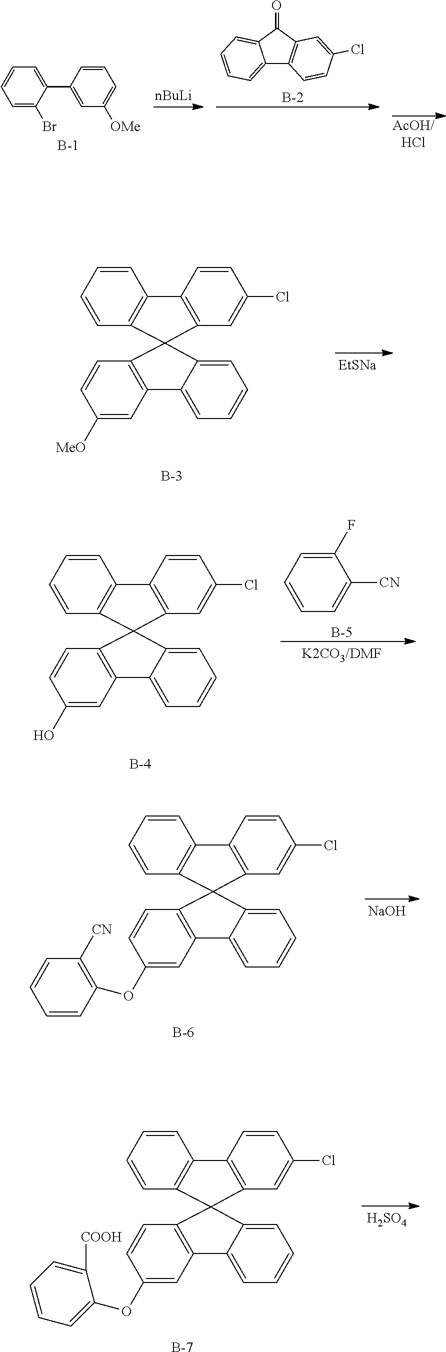

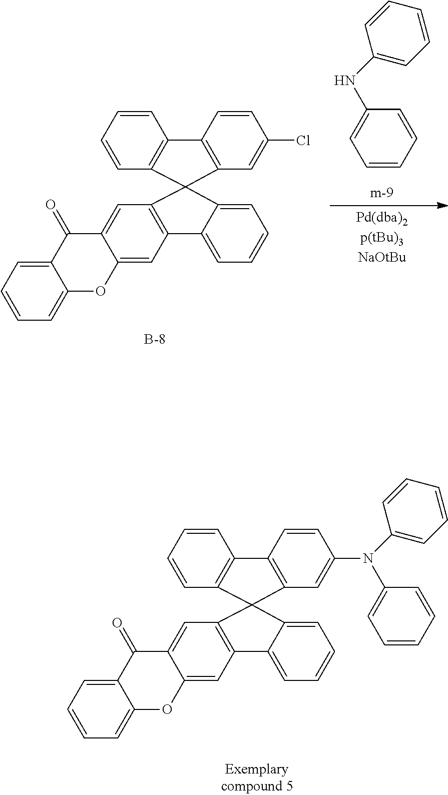

### (1) Synthesis of Compound B-3

A 500-ml recovery flask was charged with the following reagents and solvent.

Compound B-1: 5.26 g (20.0 mmol)

nBuLi (0.6 M): 35 ml (21.0 mmol)

THF: 150 ml

The reaction solution was then cooled to −78° C. in a nitrogen stream, and nBuLi was added dropwise to the reaction solution. After the dropwise addition, the reaction solution was stirred at room temperature for 2 hours. The reaction solution was cooled again to −78° C., and 30 ml of a THF solution containing 4.7 g (22.0 mmol) of Compound B-2 was added dropwise to the reaction solution. After the dropwise addition, the reaction solution was stirred at room temperature for 2 hours. The reaction solution was poured into ice water. An organic phase was extracted with toluene and was concentrated to dryness to prepare a solid.

The solid was then dissolved in 150 ml of acetic acid in a nitrogen stream, and 3 ml of concentrated hydrochloric acid was added dropwise to the reaction solution at room temperature. The reaction solution was stirred at room temperature for 5 hours. After completion of the reaction, the reaction solution was poured into ice water, and precipitated solid was filtered out. The filtered solid was purified by silica gel column chromatography (toluene:ethyl acetate mixture) to yield 4.6 g of B-3 (yield: 62%). (2) Synthesis of Compound B-4

A 300-ml recovery flask was charged with the following reagents and solvent.

Compound B-3: 4.5 g (12.2 mmol)

Sodium thioethanol:

DMF: 140 ml

The reaction solution was then heated with stirring at 60° C. for 24 hours in a nitrogen stream. After completion of the reaction, 100 ml of diluted hydrochloric acid was added to the reaction solution, and the reaction solution was filtered. 4.5 g of B-4 was obtained (yield: 96%).

### (3) Synthesis of Compound B-6

A 200-ml recovery flask was charged with the following reagents and solvent.

Compound B-4: 4.5 g (11.7 mmol)

Compound B-5: 1.6 g (12.9 mmol)

Potassium carbonate: 4.8 g (35.1 mmol)

DMF: 90 ml

The reaction solution was then heated with stirring at 100° C. for 24 hours in a nitrogen stream. After completion of the reaction, 100 ml of water was added to the reaction solution, and the reaction solution was filtered. The resulting solid was purified by silica gel column chromatography (toluene:ethyl acetate mixture) to yield 3.4 g of B-6 (yield: 63%).

### (4) Synthesis of Compound B-7

A 200-ml recovery flask was charged with the following reagents and solvents.

Compound B-6: 3.4 g (7.26 mmol)

Sodium hydroxide: 2.1 g (52.4 mmol)

Ethanol: 35 ml Water: 35 ml

The reaction solution was then heated under reflux with stirring for 7 hours in a nitrogen stream. After completion of the reaction, 100 ml of water was added to the reaction solution, and an organic phase was extracted with ethyl acetate and was concentrated to dryness. The resulting solid was dispersed and washed with toluene to yield 2.7 g of B-7 (yield: 75%).

### (5) Synthesis of Compound B-8

A 200-ml recovery flask was charged with the following reagent and solvent.

Compound B-7: 2.7 g (5.45 mmol)

Sulfuric acid: 30 ml

The reaction solution was then stirred at 100° C. for 7 hours in a nitrogen stream. After completion of the reaction, the reaction solution was poured into ice water and was filtered. The resulting solid was purified by silica gel column chromatography (chlorobenzene:ethyl acetate mixture) to yield 1.2 g of B-8 (yield: 45%).

### (6) Synthesis of Exemplary Compound 5

A 500-ml recovery flask was charged with the following reagents and solvent.

Compound B-8: 1.2 g (2.45 mmol)

Compound m-9: 0.497 g (2.94 mmol)

Sodium t-butoxide: 0.47 g (4.90 mmol)

Pd(dba)2: 70 mg

Tri-t-butylphosphine: 74 mg

o-xylene: 30 ml

The reaction solution was then heated with stirring at 140° C. for 5 hours in a nitrogen stream. After completion of the reaction, the reaction solution was filtered through Celite and was concentrated to dryness. The resulting solid was purified by silica gel column chromatography (toluene:ethyl acetate mixture) to yield 1.1 g of Exemplary Compound 5 as a yellow solid (yield: 73%).

Exemplary Compound 5 was subjected to mass spectrometry with MALDI-TOF-MS (Autoflex LRF manufactured by Bruker).

### [MALDI-TOF-MS]

Actual value: m/z =601 Calculated value: C44H27NO2 =601

Table 7 shows main physical properties of compounds used in the element evaluation. First, S₁ and T₁ energies of Exemplary Compounds 1 to 7 are shown below.

TABLE 4

| | S1 energy | T1 energy | ΔE_{S1T1} |
|---|---|---|---|
| Compound | (eV) | (eV) | (eV) |
| Exemplary compound 1 | 2.94 | 2.92 | 0.01 |
| Exemplary compound 2 | 3.18 | 2.92 | 0.26 |
| Exemplary compound 3 | 3.23 | 3.09 | 0.14 |
| Exemplary compound 4 | 2.45 | 2.37 | 0.07 |
| Exemplary compound 5 | 2.59 | 2.58 | 0.01 |
| Exemplary compound 6 | 2.98 | 2.64 | 0.34 |
| Exemplary compound 7 | 2.87 | 2.84 | 0.03 |
| Exemplary compound 8 | 3.07 | 2.40 | 0.68 |
| Exemplary compound 9 | 3.65 | 3.14 | 0.51 |
| Exemplary compound 10 | 2.49 | 2.37 | 0.12 |
| Exemplary compound 11 | 2.72 | 2.53 | 0.19 |
| EM1 | 3.14 | 2.03 | 1.11 |
| EM6 | 3.14 | 1.73 | 1.41 |
| EM15 | 3.25 | 2.03 | 1.22 |
| EM32 | 3.56 | 2.96 | 0.60 |

The exposed surface areas of the exemplary compounds and comparative compounds are shown below. For Exemplary Compound 7, the value is not a specific numerical value but a numerical range estimated from its chemical structure.

TABLE 5

| Compound | Minimum exposed surface area |
|---|---|
| Exemplary compound 1 | 60.87 |
| Exemplary compound 2 | 100.85 |
| Exemplary compound 3 | 91.84 |
| Exemplary compound 4 | 91.1 |
| Exemplary compound 5 | 57.64 |
| Exemplary compound 6 | 67.49 |
| Exemplary compound 7 | >91 |
| Exemplary compound 8 | 90.59 |
| Exemplary compound 9 | 83.09 |
| Exemplary compound 10 | 5.09 |
| Exemplary compound 11 | 10.01 |
| Exemplary compound 12 | 78.4 |
| EM1 | 86.58 |
| EM6 | 85.39 |
| EM15 | 98.41 |
| EM33 | 118.07 |

### Element Evaluation

An organic EL device of a bottom emission type produced in the present exemplary embodiment included a positive electrode, a hole-injection layer, a hole-transport layer, an electron-blocking layer, a light-emitting layer, a hole-blocking layer, an electron-transport layer, an electron-injection layer, and a negative electrode on a substrate.

An ITO film was formed on a glass substrate and was subjected to desired patterning to form an ITO electrode (positive electrode). The ITO electrode had a thickness of 100 nm. The substrate on which the ITO electrode was formed was used as an ITO substrate in the following process. Vacuum vapor deposition was then performed by resistance heating in a vacuum chamber to continuously form an organic EL layer and an electrode layer shown in Table 7 on the ITO substrate. The counter electrode (a metal electrode layer, a negative electrode) had an electrode area of 3 mm².

TABLE 6

| | | | | Film thickness |
|---|---|---|---|---|
| | Material | | | (nm) |
| Negative | Al | | | 100 |
| electrode | | | | |
| Electron- | LiF | | | 1 |
| injection | | | | |
| layer (EIL) | | | | |
| Electron- | ET2 | | | 15 |
| transport | | | | |
| layer (ETL) | | | | |
| Hole-blocking | ET12 | | | 15 |
| layer (HBL) | | | | |
| Light-emitting | First organic | EM33 | Weight ratio | 20 |
| layer (EML) | compound | | First organic | |
| | Second organic | Exemplary | compound: Second | |
| | compound | compound 1 | organic compound: | |
| | Third organic | RD1 | Third organic | |
| | compound | | compound = | |
| | | | 74.5:25:0.5 | |

| | | |
|---|---|---|
| Electron- | HT12 | 15 |
| blocking | | |
| layer (EBL) | | |
| Hole-transport | HT3 | 30 |
| layer (HTL) | | |
| Hole-injection | HT16 | 5 |
| layer (HIL) | | |

The characteristics of the element were measured and evaluated. With respect to measuring apparatuses, the current-voltage characteristics were measured with a microammeter 4140B manufactured by Hewlett-Packard Co., and the luminance was measured with a BM7 manufactured by Topcon Corporation. The external quantum efficiency (EQE) was calculated from the results and was evaluated.

The following symbols were used for the evaluation criteria for EQE.

x≤6%, 6%<A<Δ≤8%, 8%<0 10%, 10%<⊙

Furthermore, a continuous operation test was performed at a current density of 100 mA/cm², and 5% luminance degradation time (LT95) was measured. The following symbols were used for the evaluation criteria for the 5% luminance degradation time.

x≤50h, 50h<O≤100h, 100 h<⊙

For the device according to Exemplary Embodiment 1, EQE was ⊙, and LT95 was O.

### Exemplary Embodiments 2 to 24 and Comparative Examples 1 to 6

An organic light-emitting element was prepared in the same manner as in Exemplary Embodiment 1 except that Exemplary Compound 1 of the second organic compound was changed to another exemplary compound and, in another exemplary embodiment, the first organic compound was also changed to another compound. RD1 was used as a light-emitting material for red-light emission, and GD9 was used as a light-emitting material for green-light emission. The following table shows the evaluation results of the elements based on the same criteria as in Exemplary Embodiment 1.

TABLE 7

| | | | | EML | |
|---|---|---|---|---|---|
| | | | | First organic | Second organic |
| Exemplary embodiment No. | HIL | HTL | EBL | compound | compound |
| Exemplary embodiment 1 | HT16 | HT3 | HT12 | EM33 | Exemplary compound 1 |
| Exemplary embodiment 2 | HT16 | HT3 | HT11 | EM33 | Exemplary compound 4 |
| Exemplary embodiment 3 | HT16 | HT2 | HT8 | EM33 | Exemplary compound 5 |
| Exemplary embodiment 4 | HT16 | HT2 | HT8 | EM33 | Exemplary compound 6 |
| Exemplary embodiment 5 | HT16 | HT2 | HT12 | EM33 | Exemplary compound 7 |
| Exemplary embodiment 6 | HT16 | HT2 | HT12 | EM1 | Exemplary compound 4 |
| Exemplary embodiment 7 | HT16 | HT3 | HT8 | EM6 | Exemplary compound 4 |
| Exemplary embodiment 8 | HT16 | HT3 | HT8 | EM15 | Exemplary compound 4 |
| Exemplary embodiment 9 | HT16 | HT2 | HT12 | EM33 | Exemplary compound 1 |
| Exemplary embodiment 10 | HT16 | HT3 | HT8 | EM33 | Exemplary compound 2 |
| Exemplary embodiment 11 | HT16 | HT3 | HT8 | EM33 | Exemplary compound 3 |
| Exemplary embodiment 12 | HT16 | HT2 | HT8 | EM15 | Exemplary compound 5 |
| Exemplary embodiment 13 | HT16 | HT2 | HT8 | EM33 | Exemplary compound 5 |
| Exemplary embodiment 14 | HT16 | HT2 | HT8 | Exemplary compound 2 | Exemplary compound 1 |
| Exemplary embodiment 15 | HT16 | HT2 | HT8 | Exemplary compound 3 | Exemplary compound 1 |
| Exemplary embodiment 16 | HT16 | HT2 | HT8 | Exemplary compound 2 | Exemplary compound 5 |
| Exemplary embodiment 17 | HT16 | HT2 | HT8 | Exemplary compound 3 | Exemplary compound 5 |
| Exemplary embodiment 18 | HT16 | HT2 | HT8 | Exemplary compound 2 | Exemplary compound 6 |
| Exemplary embodiment 19 | HT16 | HT2 | HT8 | Exemplary compound 2 | Exemplary compound 7 |
| Exemplary embodiment 20 | HT16 | HT2 | HT8 | EM33 | Exemplary compound 4 |
| Exemplary embodiment 21 | HT16 | HT2 | HT8 | Exemplary compound 2 | Exemplary compound 4 |
| Exemplary embodiment 22 | HT16 | HT2 | HT8 | Exemplary compound 3 | Exemplary compound 4 |
| Exemplary embodiment 23 | HT16 | HT3 | HT12 | Exemplary compound 9 | Exemplary compound 2 |
| Exemplary embodiment 24 | HT16 | HT3 | HT12 | Exemplary compound 9 | Exemplary compound 2 |
| Comparative example 1 | HT16 | HT3 | HT12 | EM6 | Exemplary compound 8 |
| Comparative example 2 | HT16 | HT3 | HT12 | EM6 | Exemplary compound 8 |
| Comparative example 3 | HT16 | HT3 | HT12 | Exemplary compound 9 | Exemplary compound 10 |
| Comparative example 4 | HT16 | HT3 | HT12 | Exemplary compound 9 | Exemplary compound 11 |
| Comparative example 5 | HT16 | HT2 | HT8 | EM1 | Exemplary compound 5 |
| Comparative example 6 | HT16 | HT2 | HT8 | EM6 | Exemplary compound 5 |

| | EML | | | | |
|---|---|---|---|---|---|
| | Third organic | | | E.Q.E | LT95 |
| Exemplary embodiment No. | compound | HBL | ETL | [%] | [h] |
| Exemplary embodiment 1 | RD1 | ET12 | ET2 | ⊙ | ◯ |
| Exemplary embodiment 2 | RD1 | ET10 | ET2 | ⊙ | ⊙ |
| Exemplary embodiment 3 | RD1 | ET12 | ET3 | ⊙ | ◯ |
| Exemplary embodiment 4 | RD1 | ET12 | ET3 | ⊙ | ◯ |
| Exemplary embodiment 5 | RD1 | ET10 | ET2 | ⊙ | ⊙ |
| Exemplary embodiment 6 | RD1 | ET12 | ET2 | ◯ | ◯ |
| Exemplary embodiment 7 | RD1 | ET12 | ET2 | ◯ | ◯ |
| Exemplary embodiment 8 | RD1 | ET12 | ET2 | ◯ | ⊙ |
| Exemplary embodiment 9 | GD9 | ET12 | ET2 | ⊙ | ◯ |
| Exemplary embodiment 10 | GD9 | ET12 | ET2 | ⊙ | ⊙ |
| Exemplary embodiment 11 | GD9 | ET12 | ET2 | ⊙ | ⊙ |
| Exemplary embodiment 12 | GD9 | ET12 | ET2 | ◯ | ◯ |
| Exemplary embodiment 13 | GD9 | ET12 | ET2 | ⊙ | ◯ |
| Exemplary embodiment 14 | GD9 | ET12 | ET2 | ⊙ | ◯ |
| Exemplary embodiment 15 | GD9 | ET12 | ET2 | ⊙ | ◯ |
| Exemplary embodiment 16 | GD9 | ET12 | ET2 | ⊙ | ◯ |
| Exemplary embodiment 17 | GD9 | ET12 | ET2 | ⊙ | ◯ |
| Exemplary embodiment 18 | GD9 | ET12 | ET2 | ⊙ | ◯ |
| Exemplary embodiment 19 | GD9 | ET12 | ET2 | ⊙ | ⊙ |
| Exemplary embodiment 20 | RD1 | ET12 | ET2 | ⊙ | ⊙ |
| Exemplary embodiment 21 | RD1 | ET12 | ET2 | ⊙ | ⊙ |
| Exemplary embodiment 22 | RD1 | ET12 | ET2 | ⊙ | ⊙ |
| Exemplary embodiment 23 | GD9 | ET12 | ET2 | ⊙ | ◯ |
| Exemplary embodiment 24 | GD9 | ET12 | ET2 | ⊙ | ◯ |
| Comparative example 1 | RD1 | ET12 | ET2 | X | |
| Comparative example 2 | GD9 | ET12 | ET2 | X | |
| Comparative example 3 | RD1 | ET12 | ET2 | ◯ | X |
| Comparative example 4 | RD1 | ET12 | ET2 | ◯ | X |
| Comparative example 5 | GD9 | ET12 | ET2 | ◯ | Δ |
| Comparative example 6 | GD9 | ET12 | ET2 | ◯ | Δ |

LT95 in Comparative Examples 1 and 2 was too short to be measured. Thus, no data is provided to distinguish it from “x”.

These results show that the organic light-emitting element according to the present embodiment can have high luminescence efficiency for the following reasons.

Exemplary Embodiments 1 to 24, which had higher EQE than Comparative Examples 1 to 6, contained the second organic compound as a material system with larger spin-orbit coupling (SOC) and thereby had a high reverse intersystem crossing rate. Consequently, the organic light-emitting elements had high external quantum efficiency. It was also shown that Exemplary Compounds 1 to 7 have ΔE_{S1T1} of not more than 0.33 eV and are likely to transit from T₁to S₁ by reverse intersystem crossing.

Comparative Examples 3 and 4 have an element structure containing Comparative Compounds 3 and 4, which are known delayed fluorescent materials, and have EQE of O. In terms of durability, however, Exemplary Embodiments 1 to 24 satisfy the requirement for the exposed surface area and have an improved 5% luminance degradation time.

Furthermore, a comparison of Exemplary Embodiments 2, 5, 8, 10 to 11, and 19 to 22 with the other exemplary embodiments shows that both of the first organic compound and the second organic compound have a large minimum exposed surface area. It can be seen that this combination makes the 5% luminance degradation time of the organic light-emitting element longer.

On the other hand, Exemplary Embodiments 1 to 5, 9 to 11, and 13 to 24 have the best EQE results. This is because the first organic compound has a higher T₁ energy level than the second organic compound, and the T₁ energy is efficiently converted to the S₁ energy through the second organic compound. Furthermore, in Exemplary Embodiments 14 to 19, 21, and 22, in which the first organic compound is a delayed fluorescent material, the drive voltage of the organic light-emitting element was incidentally decreased. This is because the delayed fluorescent material used as the first organic compound for the host material of the light-emitting layer serves as a host material with low S₁ energy and decreases the barrier for charge injection from the adjacent layer.

Furthermore, a comparison between Exemplary Embodiment 5 and Exemplary Embodiment 21 shows that no rotatable single bond connecting aryl groups in the second organic compound results in high luminescence efficiency and drive durability.

### Exemplary Embodiments 25 to 51 and Comparative Examples 7 to 10

In the present embodiment, an organic light-emitting element was produced with the same structure as shown in Table 6 except that the light-emitting layer, which was a single layer, was changed to a white-light-emitting layer consisting of four layers of a red-light-emitting layer, an intermediate layer, a blue-light-emitting layer, and a green-light-emitting layer. For a light-emitting layer formed of the first to third organic compounds, the ratio between the first organic compound, the second organic compound, and the third organic compound was 74.5:25:0.5. For a light-emitting layer formed of the first and third organic compounds, the ratio of the first organic compound to the third organic compound was 99:1.

TABLE 8

| | Red-light-emitting layer | | | | Blue-light-emitting layer | |
|---|---|---|---|---|---|---|
| | First organic | Second organic | Third organic | Intermediate | First organic | Third organic |
| Exemplary embodiment No. | compound | compound | compound | layer | compound | compound |
| Exemplary embodiment 25 | EM1 | — | RD1 | EM1 | EM1 | BD1 |
| Exemplary embodiment 26 | EM1 | — | RD1 | EM1 | EM1 | BD1 |
| Exemplary embodiment 27 | EM1 | — | RD1 | EM1 | EM1 | BD1 |
| Exemplary embodiment 28 | EM1 | — | RD1 | EM1 | EM1 | BD1 |
| Exemplary embodiment 29 | EM15 | — | RD1 | EM15 | EM15 | BD1 |
| Exemplary embodiment 30 | EM15 | — | RD1 | EM15 | EM15 | BD1 |
| Exemplary embodiment 31 | EM15 | — | RD1 | EM15 | EM15 | BD1 |
| Exemplary embodiment 32 | EM15 | Exemplary compound 5 | RD1 | EM15 | EM15 | BD1 |
| Exemplary embodiment 33 | EM15 | Exemplary compound 6 | RD1 | EM15 | EM15 | BD1 |
| Exemplary embodiment 34 | EM15 | Exemplary compound 7 | RD1 | EM15 | EM15 | BD1 |
| Exemplary embodiment 35 | EM33 | Exemplary compound 1 | RD1 | EM15 | EM15 | BD1 |
| Exemplary embodiment 36 | EM33 | Exemplary compound 2 | RD1 | EM15 | EM15 | BD1 |
| Exemplary embodiment 37 | EM33 | Exemplary compound 5 | RD1 | EM15 | EM15 | BD1 |
| Exemplary embodiment 38 | EM33 | Exemplary compound 6 | RD1 | EM15 | EM15 | BD1 |
| Exemplary embodiment 39 | EM33 | Exemplary compound 1 | RD1 | EM15 | EM15 | BD1 |
| Exemplary embodiment 40 | EM33 | Exemplary compound 2 | RD1 | EM15 | EM15 | BD1 |
| Exemplary embodiment 41 | EM33 | Exemplary compound 5 | RD1 | EM15 | EM15 | BD1 |
| Exemplary embodiment 42 | EM1 | Exemplary compound 7 | RD1 | EM15 | EM15 | BD1 |
| Exemplary embodiment 43 | EM1 | Exemplary compound 7 | RD1 | EM15 | EM15 | BD1 |
| Exemplary embodiment 44 | Exemplary compound 1 | Exemplary compound 5 | RD1 | EM15 | EM15 | BD1 |
| Exemplary embodiment 45 | Exemplary compound 2 | Exemplary compound 5 | RD1 | EM15 | EM15 | BD1 |
| Exemplary embodiment 46 | Exemplary compound 1 | Exemplary compound 7 | RD1 | EM15 | EM15 | BD1 |
| Comparative example 7 | EM1 | — | RD1 | EM1 | EM1 | BD1 |
| Comparative example 8 | EM15 | — | RD1 | EM15 | EM15 | BD1 |
| Comparative example 9 | EM33 | — | RD1 | EM15 | EM15 | BD1 |
| Comparative example 10 | EM1 | — | RD1 | EM1 | EM1 | BD1 |
| Comparative example 11 | EM1 | — | RD1 | EM1 | EM1 | BD1 |
| Comparative example 12 | EM1 | — | RD1 | EM1 | EM1 | BD1 |
| Comparative example 13 | EM1 | Exemplary compound 6 | RD1 | EM15 | EM15 | BD1 |
| Comparative example 14 | EM1 | Exemplary compound 5 | RD1 | EM15 | EM15 | BD1 |
| Comparative example 15 | EM1 | Exemplary compound 6 | RD1 | EM15 | EM15 | BD1 |
| Comparative example 16 | EM1 | Exemplary compound 5 | RD1 | EM15 | EM15 | RD1 |

| | Green-light-emitting layer | | | | |
|---|---|---|---|---|---|
| Exemplary embodiment | First organic | Second organic | Third organic | E.Q.E | LT95 |
| No. | compound | compound | compound | [%] | [h] |
| Exemplary embodiment 25 | EM33 | Exemplary compound 1 | GD9 | ◯ | ◯ |
| Exemplary embodiment 26 | EM33 | Exemplary compound 2 | GD9 | ◯ | ⊙ |
| Exemplary embodiment 27 | EM33 | Exemplary compound 3 | GD9 | ◯ | ⊙ |
| Exemplary embodiment 28 | EM1 | Exemplary compound 7 | GD9 | Δ | ◯ |
| Exemplary embodiment 29 | EM15 | Exemplary compound 5 | GD9 | Δ | ◯ |
| Exemplary embodiment 30 | EM15 | Exemplary compound 6 | GD9 | Δ | ◯ |
| Exemplary embodiment 31 | EM15 | Exemplary compound 7 | GD9 | Δ | ⊙ |
| Exemplary embodiment 32 | EM15 | — | GD9 | Δ | ◯ |
| Exemplary embodiment 33 | EM15 | — | GD9 | Δ | ◯ |
| Exemplary embodiment 34 | EM15 | — | GD9 | Δ | ⊙ |
| Exemplary embodiment 35 | EM15 | — | GD9 | ◯ | ◯ |
| Exemplary embodiment 36 | EM15 | — | GD9 | ◯ | ⊙ |
| Exemplary embodiment 37 | EM15 | — | GD9 | ◯ | ◯ |
| Exemplary embodiment 38 | EM15 | — | GD9 | ◯ | ◯ |
| Exemplary embodiment 39 | EM33 | Exemplary compound 1 | GD9 | ⊙ | ◯ |
| Exemplary embodiment 40 | EM33 | Exemplary compound 2 | GD9 | ⊙ | ⊙ |
| Exemplary embodiment 41 | EM33 | Exemplary compound 1 | GD9 | ⊙ | ◯ |
| Exemplary embodiment 42 | EM33 | Exemplary compound 3 | GD9 | ◯ | ◯ |
| Exemplary embodiment 43 | EM1 | Exemplary compound 7 | GD9 | ◯ | ◯ |
| Exemplary embodiment 44 | Exemplary compound 2 | Exemplary compound 1 | GD9 | ⊙ | ◯ |
| Exemplary embodiment 45 | Exemplary compound 2 | Exemplary compound 5 | GD9 | ⊙ | ◯ |
| Exemplary embodiment 46 | Exemplary compound 2 | Exemplary compound 7 | GD9 | ⊙ | ◯ |
| Comparative example 7 | EM1 | — | GD9 | X | Δ |
| Comparative example 8 | EM15 | — | GD9 | X | Δ |
| Comparative example 9 | EM33 | — | GD9 | X | Δ |
| Comparative example 10 | EM33 | — | GD9 | X | Δ |
| Comparative example 11 | EM1 | Exemplary compound 5 | GD9 | Δ | Δ |
| Comparative example 12 | EM1 | Exemplary compound 6 | GD9 | Δ | Δ |
| Comparative example 13 | EM33 | Exemplary compound 2 | GD9 | ◯ | Δ |
| Comparative example 14 | EM33 | Exemplary compound 2 | GD9 | ◯ | Δ |
| Comparative example 15 | EM1 | Exemplary compound 6 | GD9 | ◯ | Δ |
| Comparative example 16 | EM1 | Exemplary compound 5 | GD9 | ◯ | Δ |

The characteristics of the elements were measured and evaluated. The evaluation criteria were the same as in Exemplary Embodiment 1. The organic light-emitting elements according to Exemplary Embodiments 25 to 38, in which the red- or green-light-emitting layer was a highly efficient light-emitting layer, had higher EQE than those according to Comparative Examples 7 to 10. Furthermore, the organic light-emitting elements according to Exemplary Embodiments 39 to 46, in which the red- and green-light-emitting layers had increased efficiency, had much higher EQE. Exemplary Embodiments 39 to 41 and 44 to 46 had higher EQE than Comparative Examples 13 to 16. This is because due to a higher T₁ energy level of the first organic compound the T₁ energy was efficiently converted to S₁ energy in the second organic compound.

The present disclosure is not limited to Exemplary Embodiments 1 to 46. For example, although Exemplary Embodiments 1 to 46 have a bottom emission structure, the electrode materials may be changed to provide a top emission structure. In another embodiment, when at least the light-emitting layer is divided on a subpixel basis in accordance with the emission color of each light-emitting pixel, one of the subpixels may be an organic light-emitting element according to the present disclosure. The layer structure for a white-light-emitting element is not limited to the exemplary embodiments in the present disclosure. More specifically, various modifications may be made in the stacking sequence of light-emitting layers, the presence or absence of an intermediate layer and the position at which the intermediate layer is inserted, the number of light-emitting layers to be stacked, and multicolor emission from the light-emitting layer. An organic light-emitting element according to the present disclosure may be sealed in any form.

The present disclosure can improve the durability of an organic light-emitting element including a delayed fluorescent material.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2021-008438 filed Jan. 22, 2021, which is hereby incorporated by reference herein in its entirety.

What is claimed is:

1. An organic light-emitting element, comprising:
a first electrode;
a second electrode; and
a light-emitting layer located between the first electrode and the second electrode,
wherein the light-emitting layer contains a first organic compound, a second organic compound that has lower lowest excited singlet energy than the first organic compound and is a delayed fluorescent material, and a third organic compound that is a light-emitting material with lower lowest excited singlet energy than the second organic compound,
at least one of an exposed surface area of a single bond in a structure of the first organic compound and an exposed surface area of a single bond in a structure of the second organic compound is 91 or more, and
the second organic compound has a larger exposed surface area of the single bond than the first organic compound.

2. The organic light-emitting element according to claim 1, wherein the exposed surface area of the single bond in the structure of the first organic compound is 91 or more.

3. The organic light-emitting element according to claim 2, wherein the exposed surface area of the single bond in the structure of the first organic compound is 100 or more.

4. The organic light-emitting element according to claim 1, wherein the exposed surface area of the single bond in the structure of the second organic compound is 91 or more.

5. The organic light-emitting element according to claim 4, wherein the exposed surface area of the single bond in the structure of the second organic compound is 100 or more.

6. The organic light-emitting element according to claim 1, wherein the second organic compound is represented by the formula [1]: 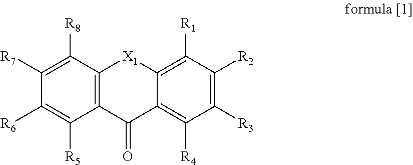
wherein R₁ to R₈ independently denote a hydrogen atom, a halogen atom, a substituted or unsubstituted alkyl group, a substituted or unsubstituted alkoxy group, a substituted or unsubstituted amino group, a substituted or unsubstituted aromatic hydrocarbon group, a substituted or unsubstituted heterocyclic group, a substituted or unsubstituted aryloxy group, a silyl group, or a cyano group, at least adjacent two of R₁ to R₈ are bonded together to form a ring structure, and any one of R₁ to R₈ denotes the amino group, and the amino group may have substituents bonded together to form a ring structure,
X₁ denotes oxygen, sulfur, selenium, tellurium, or a CY₁Y₂ group, and
Y₁ and Y₂ independently denote a hydrogen atom, a halogen atom, a substituted or unsubstituted alkyl group, a substituted or unsubstituted alkoxy group, a substituted or unsubstituted amino group, a substituted or unsubstituted aryl group, a substituted or unsubstituted heterocyclic group, a substituted or unsubstituted aryloxy group, a silyl group, or a cyano group.

7. The organic light-emitting element according to claim 1, further comprising another light-emitting layer between the first electrode and the second electrode to emit white light.

8. The organic light-emitting element according to claim 1, further comprising a hole-transport layer in contact with the light-emitting layer between the first electrode and the light-emitting layer, wherein the hole-transport layer has higher lowest excited triplet energy than the second organic compound.

9. The organic light-emitting element according to claim 1, further comprising an electron-transport layer in contact with the light-emitting layer between the second electrode and the light-emitting layer, wherein the electron-transport layer has higher lowest excited triplet energy than the second organic compound.

10. The organic light-emitting element according to claim 1, further comprising: a second light-emitting layer different from the light-emitting layer,
wherein the second light-emitting layer contains a fourth organic compound that has lowest excited singlet energy equal to or lower than the lowest excited singlet energy of the first organic compound, a fifth organic compound that has lower lowest excited singlet energy than the fourth organic compound and is a delayed fluorescent material, and a sixth organic compound that has lower lowest excited singlet energy than the fifth organic compound and lower lowest excited singlet energy than the third organic compound, and
at least one of an exposed surface area of a single bond in a structure of the fourth organic compound and an exposed surface area of a single bond in a structure of the fifth organic compound is 91 or more.

11. The organic light-emitting element according to claim 10, wherein the exposed surface area of the single bond in the structure of the fourth organic compound is 91 or more.

12. The organic light-emitting element according to claim 11, wherein the exposed surface area of the single bond in the structure of the fourth organic compound is 100 or more.

13. The organic light-emitting element according to claim 10, wherein the exposed surface area of the single bond in the structure of the fifth organic compound is 91 or more.

14. The organic light-emitting element according to claim 13, wherein the exposed surface area of the single bond in the structure of the fifth organic compound is 100 or more.

15. The organic light-emitting element according to claim 10, wherein the fifth organic compound has a larger exposed surface area of the single bond than the fourth organic compound.

16. A display apparatus comprising a plurality of pixels, wherein at least one of the plurality of pixels includes the organic light-emitting element according to claim 1 and a transistor coupled to the organic light-emitting element.

17. A photoelectric conversion apparatus comprising:
an optical unit with a plurality of lenses;
an imaging element configured to receive light passing through the optical unit; and
a display unit configured to display an image taken by the imaging element,
wherein the display unit includes the organic light-emitting element according to claim 1.

18. Electronic equipment comprising:
a display unit including the organic light-emitting element according to claim 1;
a housing in which the display unit is provided; and
a communication unit configured to communicate with an outside provided in the housing.

19. A lighting apparatus comprising:
a light source including the organic light-emitting element according to claim 1; and
a light-diffusing unit or an optical film that transmits light emitted by the light source.

20. A moving body comprising:
a lamp including the organic light-emitting element according to claim 1; and
a body to which the lamp is provided.
